(19) United States
(12) Patent Application Publication
(10) Pub. No.: US 2019/0123222 A1
(43) Pub. Date: Apr. 25, 2019

(54) SOLAR CELL, SOLAR CELL DEVICE, AND MANUFACTURING METHOD

(71) Applicant: SHARP KABUSHIKI KAISHA, Sakai City, Osaka (JP)

(72) Inventor: SATOSHI SHIBATA, Sakai City (JP)

(21) Appl. No.: 16/093,089

(22) PCT Filed: Aug. 3, 2016
(86) PCT No.: PCT/JP2016/072859

§ 371 Date: Oct. 11, 2018

(30) Foreign Application Priority Data
Apr. 14, 2016 (JP) 2016-081435

(51) Int. Cl. H01L 31/0224; H01L 31/028; H01L 31/14; H01L 31/068; H01L 31/054; H01L 31/18

(52) U.S. Cl. CPC H01L 31/022441; H01L 31/028; H01L 31/1804; H01L 31/0682; H01L 31/0543; H01L 31/143

(57) ABSTRACT

Provided is a solar cell device and a manufacturing method thereof, whereby decrease in electricity generating efficiency of a solar cell, of which the manufacturing process includes a cutting processing, can be suppressed. The solar cell device includes a solar cell and a fluorescent light collector, and both ends of the solar cell along the long side are formed by dicing, at a second region where a minority carrier is generated, between a first electrode and a second electrode.

### TECHNICAL FIELD

The present invention relates to a solar cell, a solar cell device, and a manufacturing method thereof.

### BACKGROUND ART

In recent years, the importance of solar cells as a clean energy source has been recognized, and demand thereof is increasing year after year. Solar cell modules, using solar cells having N electrodes and P electrodes on a light-receiving face and rear face, respectively, of a silicon substrate, are in widespread use as solar cells. Rear-contact type solar cells, where P electrodes and N electrodes are formed on the rear face of a silicon substrate, have also been developed.

Rear-contact type solar cells enable increased photoelectric conversion efficiency, since the electrodes can be concentrated on the rear face and electrodes on the light-receiving face can be done away with, so the area of the light-receiving face can be increased accordingly, and more light be taken in. Accordingly, development of solar cells using rear-contact type solar cells is being advanced.

For example, PTL 1 discloses a rear-contact type solar cell, and a solar cell manufacturing method is disclosed that includes a step of forming first and second electrodes in a first principal face of a photoelectric conversion unit, and a step of cutting a portion of the photoelectric conversion unit by cutting the photoelectric conversion unit along a cut line that passes over at least one electrode of the first and second electrodes. Also disclosed is, in the step of cutting, preferably cutting a region of the photoelectric conversion unit where only an electrode provided to a side where the majority carrier is collected. PTL 1 states that by doing so, loss due to recombination of the minority carrier can be suppressed, and improved photoelectric conversion properties can be obtained.

### CITATION LIST

### Patent Literature

PTL 1: International Publication No. 2013/042222 (International Publication date: Mar. 28, 2013)

### SUMMARY OF INVENTION

### Technical Problem

However, in a case of fabricating strip-shaped relatively-small solar cells as suggested in PTL 1 by cutting a region of the photoelectric conversion unit at a side where the majority carrier is collected, the narrower the strips are, the greater the effect of decrease in photoelectric conversion properties at the diced edge portions is, so the amount of electricity generated per unit of light-receiving area markedly decreases, and electricity generating efficiency decreases. Also, metal shards fly from electrodes when dicing electrodes, and the metal shards adhere to other wiring regions, causing leakage. Further, applying a dicing blade to metal wiring portions results in occurrence of so-called chipping defects, where the cut face is rough, or cracking, nicking, and so forth occurs at the cut face.

The present invention has been made in light of the above-described problem, and it is an object thereof to provide a solar cell and solar cell device that can suppress decrease in electricity generating efficiency of a solar cell of which the manufacturing steps include a cutting step, and a manufacturing method thereof.

### Solution to Problem

In order to solve the above-described problems, a solar cell according to an aspect of the present invention is a solar cell of a rear-contact type, including: a first-conductivity type substrate; a first region made up of a first diffusion layer formed on the substrate and extending in a first direction as a predetermined direction, where a first carrier of a first conductivity type is generated; a second region made up of a second diffusion layer formed on the substrate and extending in the first direction, where a second carrier of a second conductivity type that differs from the first conductivity type is generated; a first electrode disposed in the first region; and a second electrode disposed in the second region. On a rear face side of the substrate of a quadrangular shape that has at least two sides parallel with the first direction, a plurality of the first region and the second region are formed alternating along a second direction that intersects the first direction. The second region is exposed at cut faces of the solar cell that include the two sides and that follow a thickness direction of the substrate.

In order to solve the above-described problems, a solar cell device according to an aspect of the present invention is a solar cell device including a solar cell and a light collector that has a light-emitting face facing a light-receiving face of the solar cell. The solar cell is a rear-contact type solar cell, including a first-conductivity type substrate, a first region made up of a first diffusion layer formed on the substrate and extending in a first direction as a predetermined direction, where a first carrier of a first conductivity type is generated, a second region made up of a second diffusion layer formed on the substrate and extending in the first direction, where a second carrier of a second conductivity type that differs from the first conductivity type is generated, a first electrode disposed in the first region, and a second electrode disposed in the second region. On a rear face side of the substrate of a quadrangular shape that has at least two sides parallel with the first direction, a plurality of the first region and the second region are formed alternating along a second direction that intersects the first direction. The second region is exposed at cut faces of the solar cell that include the two sides and that follow a thickness direction of the substrate.

In order to solve the above-described problems, a solar cell device according to an aspect of the present invention is a solar cell device including a solar cell and a light collecting member that has a light-emitting face facing a light-receiving face of the solar cell. The solar cell is a rear-contact type solar cell, including a first-conductivity type substrate, a first region made up of a first diffusion layer formed on the substrate and extending in a first direction as a predetermined direction, where a first carrier of a first conductivity type is generated, a second region made up of a second diffusion layer formed on the substrate and extending in the first direction, where a second carrier of a second conductivity type that differs from the first conductivity type is generated, a first electrode disposed in the first region, and a second electrode disposed in the second region. On a rear face side of the substrate of a quadrangular shape that has at least two sides parallel with the first direction, a plurality of the first region and the second region are formed alternating along a second direction that intersects the first direction. The second region is exposed at cut faces of the solar cell that include the two sides and that follow a thickness direction of the substrate.

In order to solve the above-described problems, a manufacturing method of a solar cell according to an aspect of the present invention includes: forming, on a first-conductivity type substrate, a first region made up of a first diffusion layer where a first carrier of a first conductivity type is generated, and a second region made up of a second diffusion layer where a second carrier of a second conductivity type that differs from the first conductivity type is generated, each extending in a first direction as a predetermined direction, the first region and the second region being formed alternating along a second direction that intersects the first direction; forming a first electrode in the first region, and a second electrode in the second region; and cutting the second region between the first electrode and the second electrode following the first direction, thereby fabricating a quadrangle-shaped solar cell having two sides parallel with the first direction.

In order to solve the above-described problems, a manufacturing method of a solar cell device according to an aspect of the present invention is a manufacturing method of a solar cell device including a solar cell and a light collector, the method including: forming, on a first-conductivity type substrate, a first region made up of a first diffusion layer where a first carrier of a first conductivity type is generated, and a second region made up of a second diffusion layer where a second carrier of a second conductivity type that differs from the first conductivity type is generated, each extending in a first direction as a predetermined direction, the first region and the second region being formed alternating along a second direction that intersects the first direction; forming a first electrode in the first region, and a second electrode in the second region; cutting the second region between the first electrode and the second electrode following the first direction, thereby fabricating a quadrangle-shaped solar cell having two sides parallel with the first direction; and assembling the light collector with the light-emitting face of the light collector facing the light-receiving face of the fabricated solar cell.

In order to solve the above-described problems, a manufacturing method of a solar cell device according to an aspect of the present invention is a manufacturing method of a manufacturing method of a solar cell device including a solar cell and a light collecting member, the method including: forming, on a first-conductivity type substrate, a first region made up of a first diffusion layer where a first carrier of a first conductivity type is generated, and a second region made up of a second diffusion layer where a second carrier of a second conductivity type that differs from the first conductivity type is generated, each extending in a first direction as a predetermined direction, the first region and the second region being formed alternating along a second direction that intersects the first direction; forming a first electrode in the first region, and a second electrode in the second region; cutting the second region between the first electrode and the second electrode following the first direction, thereby fabricating a quadrangle-shaped solar cell having two sides parallel with the first direction; and assembling the light collecting member with the light-emitting face of the light collecting member facing the light-receiving face of the fabricated solar cell.

### Advantageous Effects of Invention

According to the above-described aspects of the present invention, an advantage can be yielded where decrease in electricity generating efficiency of a solar cell of which the manufacturing steps include a cutting step can be suppressed.

### BRIEF DESCRIPTION OF DRAWINGS

FIG. 1 is a cross-sectional view schematically illustrating the configuration of a solar cell according to a first embodiment of the present invention, and dicing lines.

FIG. 2 is a plan view schematically illustrating the electrode patterns of the solar cell according to the first embodiment of the present invention, and dicing lines.

FIG. 3 is an image based on a photograph analyzing a state in the solar cell according to the first embodiment of a present invention where photocarriers have been generated.

FIG. 4 illustrates microscope photographs of a solar cell as a comparative example diced at a first electrode, where (a) is an image of a rear face (non-light-receiving face), and (b) is an image of a front face (light-receiving face).

FIG. 5 illustrates microscope photographs of a solar cell according to the first embodiment, diced at a second region, where (a) is an image of a rear face (non-light-receiving face), and (b) is an image of a front face (light-receiving face).

FIG. 6 is a plan view schematically illustrating the positional relation between dicing lines and regions with lower properties that occur.

FIG. 7 is a plan view schematically illustrating a solar cell device according to the first embodiment of the present invention.

FIG. 8 is a plan view schematically illustrating the solar cell device according to the first embodiment of the present invention.

FIG. 9 is a plan view explanatorily illustrating the relation between the width of the solar cell according to the first embodiment of the present invention and the pitch at which electrodes are formed on the rear side, and the width of a fluorescent light collector.

FIG. 10 schematically illustrates the configuration of a fluorescent light collecting solar cell, where (a) is a perspective view, (b) is a cross-sectional view, and (c) is an enlarged cross-sectional view.

FIG. 11 is a graph illustrating wavelength distribution of emission energy of a fluorescent light spectrum and solar light spectrum.

FIG. 12 is a plan view schematically illustrating electrode patterns and dicing lines of a solar cell according to a second embodiment of the present invention.

FIG. 13 is a plan view schematically illustrating electrode patterns and dicing lines of a solar cell according to a third embodiment of the present invention.

FIG. 14 is images illustrating an application example of a solar cell device according to a fourth embodiment of the present invention.

FIG. 15 is images illustrating an application example of a solar cell device according to the fourth embodiment of the present invention.

FIG. 16 is a cross-sectional view schematically illustrating the configuration and dicing lines of a solar cell according to a fifth embodiment of the present invention.

FIG. 17 illustrates the solar cell according to the fifth embodiment of the present invention, where (a) is a plan view schematically illustrating the positional relation between dicing lines and regions with lower properties that occur, and (b) is a cross-sectional view schematically illustrating a cut face after cutting the solar cell illustrated in (a) following the dicing lines in (a).

FIG. 18 illustrates a strip-shaped solar cell according to the fifth embodiment of the present invention, where (a) and (b) are a cross-sectional view and plan view schematically illustrating electrode patterns thereof, and (c) and (d) are a cross-sectional view and plan view schematically illustrating electrode patterns of a strip-shaped solar cell according to a sixth embodiment of the present invention for comparison.

FIG. 19 is a plan view schematically illustrating the configuration of a solar cell device according to the fifth embodiment of the present invention.

FIG. 20 is a plan view schematically illustrating the electrode patterns of a strip-shaped solar cell according to the fifth embodiment of the present invention.

FIGS. 21 (a) and (b) are plan views schematically illustrating two examples, as margin setting examples when assembling a light collector to the strip-shaped solar cell according to the fifth embodiment of the present invention.

FIGS. 22 (a) and (b) are plan views schematically illustrating examples of positional deviation occurring examples when assembling a light collector to the strip-shaped solar cell according to the fifth embodiment of the present invention, respectively correlating to (a) and (b) in FIG. 21.

FIG. 23 is a plan view schematically illustrating the configuration and dicing lines of the solar cell according to the sixth embodiment of the present invention.

FIG. 24 is a plan view schematically illustrating the electrode pattern and dicing lines of the solar cell according to the sixth embodiment of the present invention.

FIG. 25 is a plan view schematically illustrating the positional relation between dicing lines and regions with lower properties that occur in the solar cell according to the sixth embodiment of the present invention.

FIG. 26 is a plan view illustrating various types of parameters relating to the structure of the strip-shaped solar cell according to the sixth embodiment of the present invention, and explanatorily illustrating the relation between the width of the solar cell and the width of the fluorescent light collector.

FIG. 27 is a plan view schematically illustrating the electrode patterns of a strip-shaped solar cell according to a modification of the sixth embodiment of the present invention.

FIGS. 28 (a) and (b) are plan views schematically illustrating two examples, as margin setting examples when assembling a light collector to the strip-shaped solar cell according to the sixth embodiment of the present invention.

FIGS. 29 (a) and (b) are plan views schematically illustrating examples of positional deviation occurring when assembling a light collector to the strip-shaped solar cell according to the sixth embodiment of the present invention, respectively correlating to (a) and (b) in FIG. 28.

FIG. 30 (a) through (h) are cross-sectional views and top views explanatorily illustrating four examples of solar cell devices where optical elements having functions of condenser lenses have been assembled to solar cells as light collecting members.

### DESCRIPTION OF EMBODIMENTS

### First Embodiment

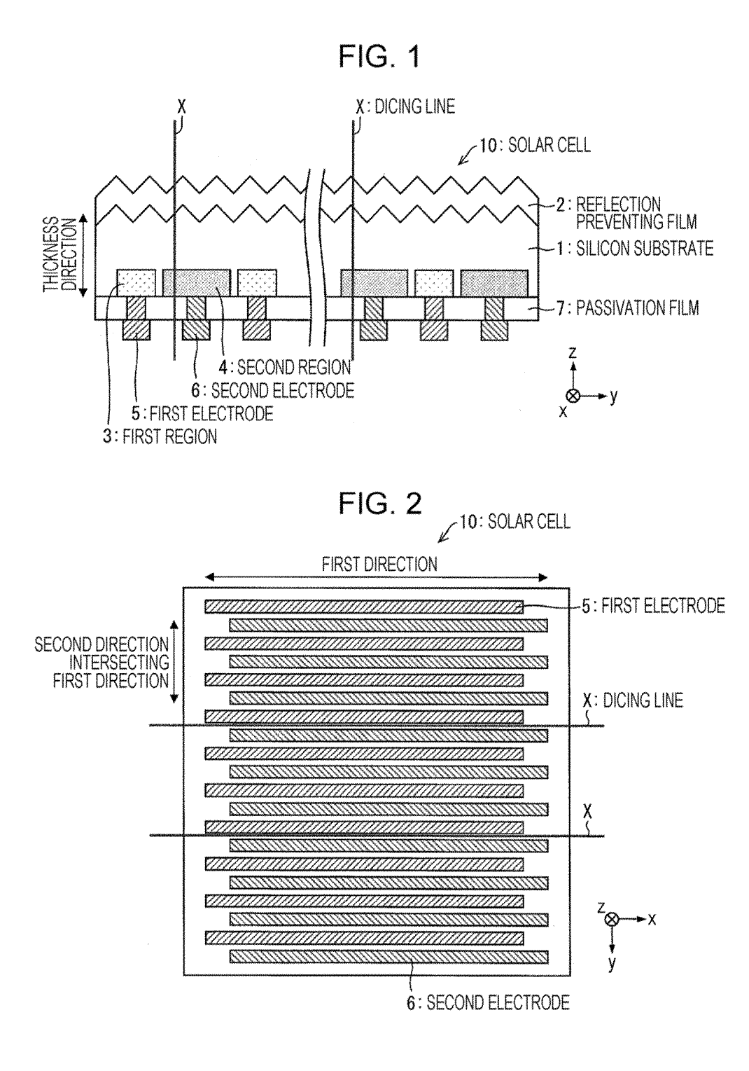

An embodiment of the present invention will be described below in detail, with reference to FIGS. 1 through 15.

### <Configuration of Solar Cell Device>

The solar cell device according to the present embodiment relates to a light collecting solar cell having a solar cell and fluorescent light collector, with the light-receiving face of the solar cell and the light-emitting face of the fluorescent light collector being disposed facing each other.

### (Configuration of Solar Cell 10)

FIG. 1 is a cross-sectional view schematic illustrating the configuration and dicing lines of the solar cell 10 according to the present first embodiment, and FIG. 2 is a plan view schematically illustrating electrode patterns and dicing lines of the solar cell 10 according to the present first embodiment. The solar cell 10 includes a silicon substrate 1 serving as a first-conductivity type substrate, a reflection preventing film 2, a first region 3 made up of a first diffusion layer, a second region 4 made up of a second diffusion layer, a first electrode 5, a second electrode 6, and a passivation film 7, as illustrated in FIG. 1. The outer face of the reflection preventing film 2 is the light-receiving face of the solar cell 10. The reflection preventing film 2 is formed on the light-receiving face side of the silicon substrate 1, and the first region 3, second region 4, and passivation film 7 are formed on the rear face side of the silicon substrate 1. Note that a configuration may be made where a passivation film is further provided between the silicon substrate 1 and reflection preventing film 2.

The first region 3 is a region where the majority carrier of the photoelectric conversion unit (the carrier of the aforementioned first-conductivity type) is generated, and the second region 4 is a region where the minority carrier of the photoelectric conversion unit (the carrier of a second-conductivity type that is different from the aforementioned first-conductivity type) is generated. The shapes of the first region 3 and second region 4 are each generally band-like in plain view, and multiple are formed alternately in a certain direction on the rear side of the silicon substrate 1. For example, in a case where the shape of the silicon substrate 1 in plain view is a rectangle, the aforementioned certain direction is a direction following one side of the rectangle, with the first region 3 and second region 4 extending along other sides that intersect with that one side. The aforementioned certain direction is a direction that regulates the widths of the first region 3, second region 4, and the first electrode and second electrode described below.

The directions relating to be the solar cell 10 will be redefined here using mutually orthogonal x, y, and z axes, as illustrated in FIG. 1 and FIG. 2. The direction in which the first region 3, second region 4, first electrode 5, and second electrode 6 each extend is the x direction (first direction as a predetermined direction). The x direction also is the longitudinal direction of the solar cell 10. The direction where the first region 3 and first electrode 5, and the second region 4 and second electrode 6, are disposed in an alternating manner to each other, is the y direction (second direction intersecting the first direction). The y direction also is the width direction of the solar cell 10. The thickness direction of the solar cell 10 is the z direction. The shape of the silicon substrate 1 can be said to be a quadrangular shape that has at least two sized parallel to the x direction (first direction). The aforementioned two sides that are parallel are illustrated as L1 and L2 in a later-described FIG. 7.

The width of bands of the second region 4, which is the region where the minority carrier is generated, is preferably broader than the width of bands of the first region 3 which is the region where the majority carrier is generated. This configuration enables a margin for dicing to be secured when dicing, which will be described later.

The first electrode is disposed on the first region 3, and the second electrode is disposed on the second region 4. The shapes of the first electrode and second electrode in plain view are also generally band-like shapes, as illustrated in FIG. 2. However, the widths of the first electrode and second electrode are set to being narrower than 1 mm for example, so the first electrode and second electrode in plain view can also said to be line shaped. Note that the width of the second region 4 preferably is wider than the width of the first region 3, since the second region 4 is the region where the minority carrier is generated, but the width of the first region 3 and the width of the second region 4 may be the same.

The first-conductivity type silicon substrate 1 may be an N-type silicon substrate, or may be a P-type silicon substrate. In a case of using an N-type silicon substrate as the silicon substrate 1, the minority carrier is generated in the P region, so the first region 3 is an N region of the same conductivity type as the silicon substrate 1, the second region 4 is a P region of a different conductivity type from the silicon substrate 1, the first electrode 5 is an N electrode, and the second electrode 6 is a P electrode. On the other hand, in a case of using a P-type silicon substrate as the silicon substrate 1, the minority carrier is generated in the N region, so the first region 3 is a P region of the same conductivity type as the silicon substrate 1, the second region 4 is an N region of a different conductivity type from the silicon substrate 1, the first electrode 5 is a P electrode, and the second electrode 6 is an N electrode.

The reflection preventing film 2 and passivation film 7 can be formed from a silicon nitride film or silicon oxide film, for example.

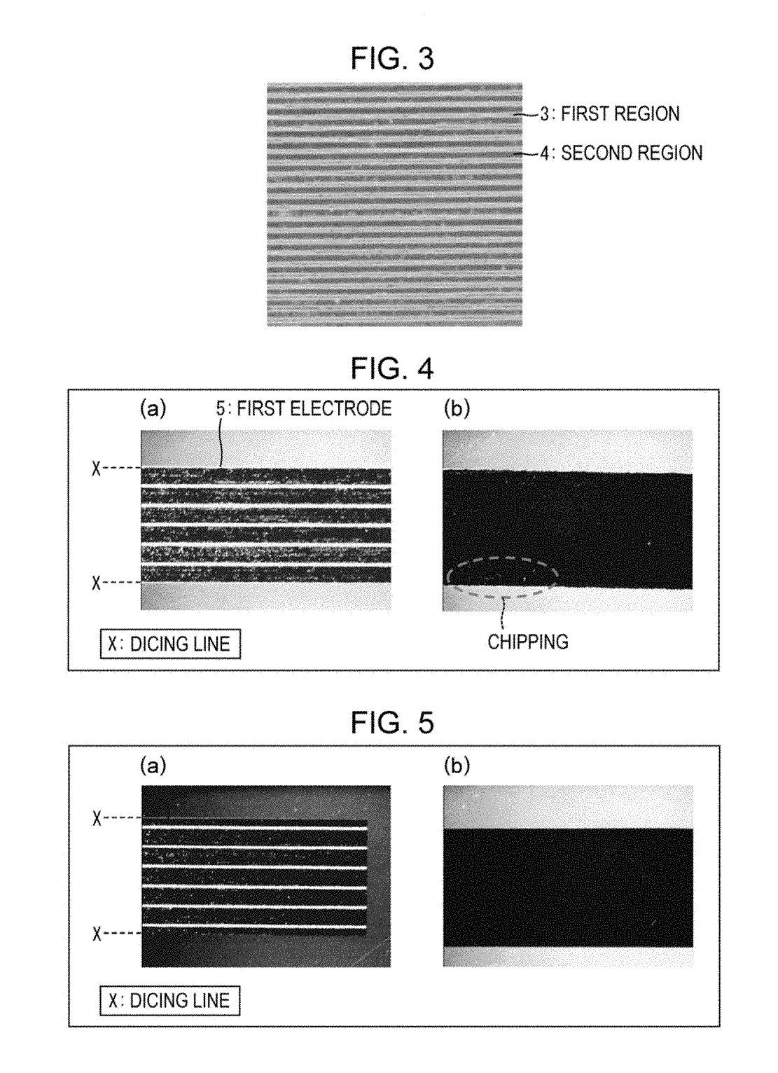

FIG. 3 is an image based on a photograph analyzing a state in which photocarriers have been generated in the solar cell 10 according to the present first embodiment. The first region 3 and second region 4 are observed as being separated, and the first region 3 and second region 4 are formed in an alternative manner, as illustrated in FIG. 3. This also shows that the width of the first region 3 is formed wider than the width of the second region 4.

### (Configuration of Solar Cell Device)

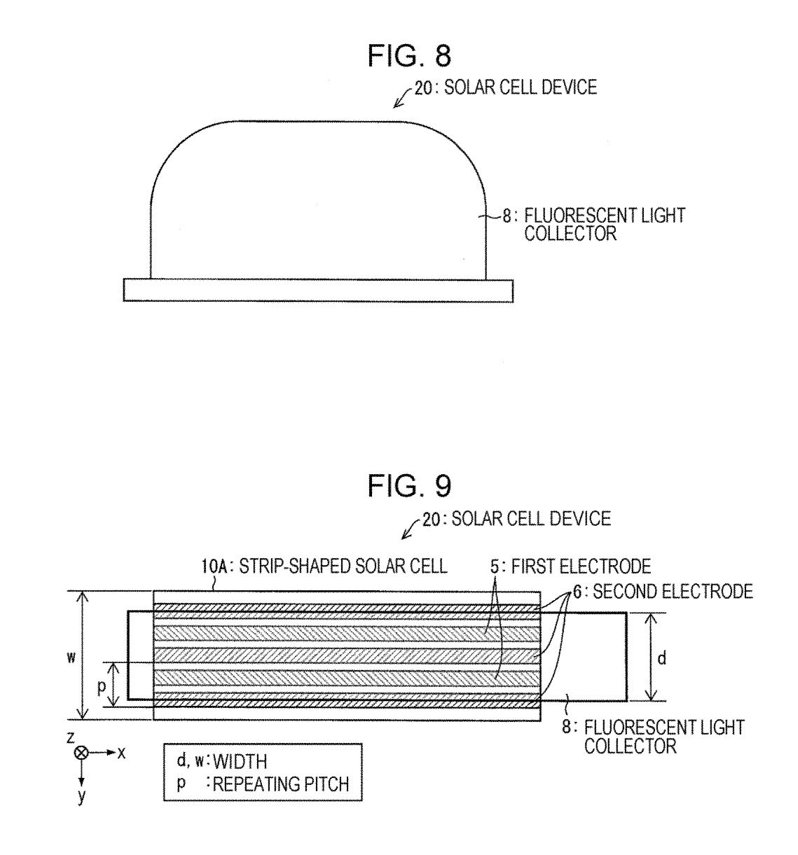

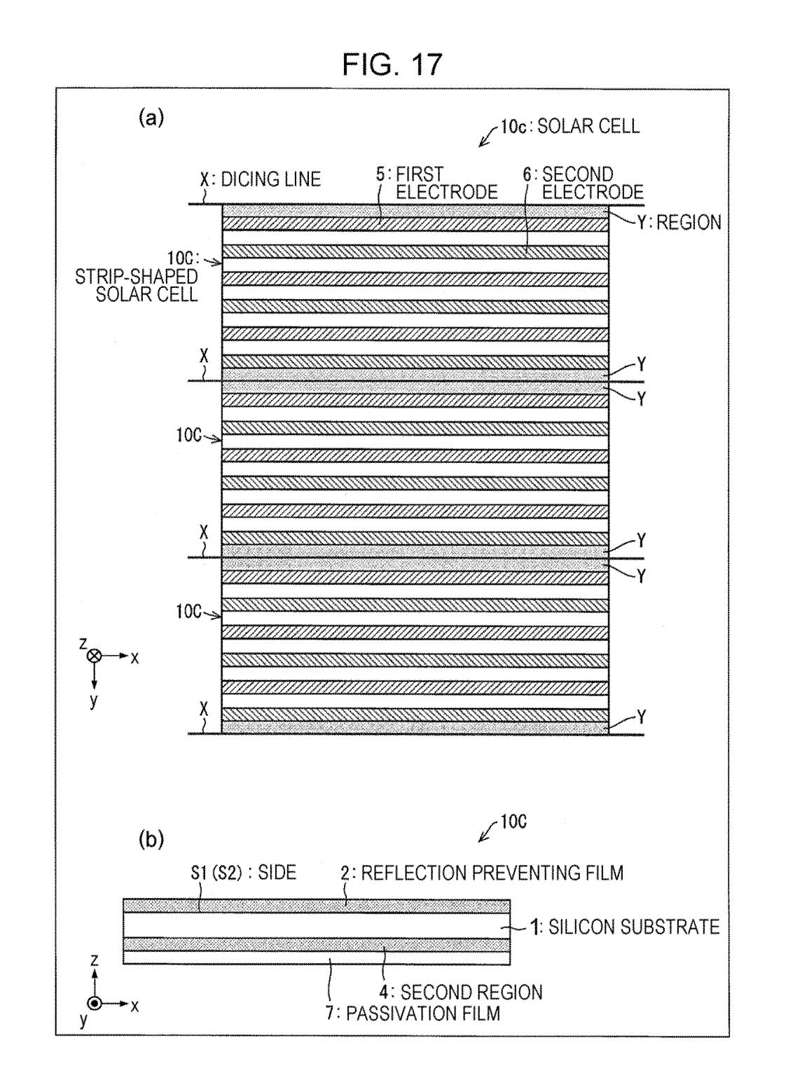

A solar cell device 20 according to the present first embodiment is made up of a combination of a solar cell 10A obtained by cutting the solar cell 10 into strips, and a fluorescent light collector 8, as illustrated in FIG. 7 and FIG. 8, which will be described later in detail. Dicing lines X are set in the solar cell 10 between the first electrode 5 and second electrode 6, as illustrated in FIG. 1 and FIG. 2, to cut the solar cells 10A out of the solar cell 10. The dicing lines X are parallel to the thickness direction of the solar cell 10, and are set to cut the second region 4 but not cut the first electrode 5 and second electrode 6. As a result, the second region 4 is exposed at the cut face of the solar cell 10A along the dicing lines X (see later-described FIG. 17(b)), and the second electrode 6 disposed above the second region 4 of which the cut face is exposed is situated on the onward side from the cut face (toward the middle of the solar cell 10A). The results of comparison with a solar cell 10 diced so as to cut the first electrode 5 and a solar cell 10 diced so as to cut the second region 4 between the first electrode 5 and second electrode 6 are described below.

FIG. 4 illustrates observation results of the solar cell 10 serving as a comparative example, which has been diced so as to cut the first electrode 5, where (a) is a microscope photograph of the rear face (non-light-receiving face) of the solar cell 10, and (b) is a microscope photograph of the front face (light-receiving face) of the solar cell 10. A state where the diced first electrode 5 is remaining is observed at the edge of the diced solar cell 10, as illustrated in (a) in FIG. 4. Also, chipping defects described as a problem for the present invention to solve were observed at the edge of the diced solar cell 10 as illustrated in (b) in FIG. 4, due to dicing on the first electrode 5.

On the other hand, FIG. 5 illustrates the observation results of the solar cell 10 diced so as to cut the second region 4, where (a) is a microscope photograph image of the rear face (non-light-receiving face) of the solar cell 10, and (b) is a microscope photograph image of the front face (light-receiving face) of the solar cell 10. No defects such as chipper are observed at the edge of the diced solar cell 10, as illustrated in (a) and (b) in FIG. 5, since dicing has been performed to cut the second region 4 between the first electrode 5 and second electrode 6 of the solar cell 10 illustrated in FIG. 5.

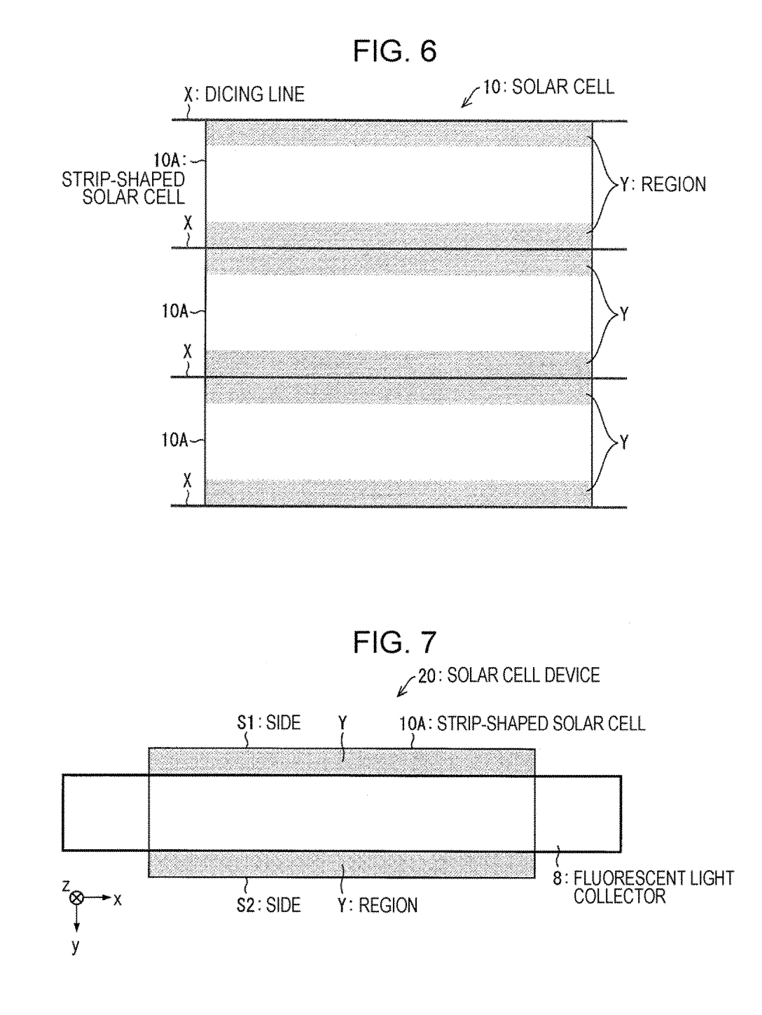

FIG. 6 is a plan view schematically illustrating the positional relation between dicing lines X and regions with lower properties that occur. In a case of dicing the solar cell 10 so as to cut the second region 4 and fabricate strip-shaped solar cells 10A, regions Y where photoelectric conversion properties have become lower occur at the edges of the solar cell 10A along the long sides, i.e., on the inner side of the cut faces, as illustrated in FIG. 6. The second region 4 is the region where the minority carrier is generated, so photoelectric conversion properties fall due to recombination of minority carriers at the edges of the solar cells 10A along the long sides. On the other hand, the first electrode 5 and second electrode 6 are arrayed in an alternating manner, so there is a region other than the diced edge portions between the first electrode 5 and second electrode 6, i.e., the region near the middle portion. Accordingly, the minority carrier is collected by the second electrode 6 without being affected by the region Y with lower photoelectric conversion properties, so there is no decrease in photoelectric conversion properties.

The following table illustrates measurement results of I-V properties of the solar cell 10A diced at the first electrode 5 and second region 4.

TABLE 1

| | Open | Current | | Serial | Parallel |
|---|---|---|---|---|---|
| | voltage | density | | resistance | resistance |
| | [V] | [mA/cm²] | Fill Factor | [Ω] | [Ω] |
| Before | 0.48 | 0.14 | 0.66 | — | — |
| dicing | | | | | |
| Dicing on | 0.4 | 0.13 | 0.58 | 1.24 | 5.60E+04 |
| electrode | | | | | |
| Dicing in | 0.41 | 0.06 | 0.6 | 0.6 | 1.20E+05 |
| second | | | | | |
| region | | | | | |

As illustrated in FIG. 6, the photoelectric conversion properties of the region Y of the solar cell 10A diced at the second region 4 have dropped, and electricity generating efficiency is lower, so the fact that the electricity generating efficiency per unit area of the solar cell 10A is lower than the solar cell diced on the first electrode 5 is markedly manifested as lower current density. The solar cell device 20 according to the present first embodiment has the fluorescent light collector 8 disposed at the middle of the solar cell 10A excluding the region Y where the photoelectric conversion properties are lower, so that the light-receiving face of the solar cell 10A and the light-emitting face of the fluorescent light collector 8 face each other, as illustrated in FIG. 7, in order to suppress or to compensate for decrease in electricity generating efficiency of the solar cell 10.

The fluorescent light collector 8 is disposed only in the region where the photoelectric conversion properties are not lower in the solar cell device 20 according to the present first embodiment, thereby narrowing down the effective light-receiving area of the solar cell 10 and accordingly the effects of lowered photoelectric conversion properties can be suppressed, and photoelectric conversion properties can be improved instead. A solar cell device 20 in which quality solar cells 10A with suppressed chipping defects have been mounted can be provided, since the solar cell 10 has not been diced cutting electrodes.

### (Detailed Configuration of Solar Cell Device)

A further detailed configuration of the solar cell device 20 will be described with reference to FIGS. 8 and 9. FIG. 8 is a frontal view of the solar cell device 20 according to the present first embodiment, and FIG. 9 is a plan view explanatorily illustrating the relation between the width of the solar cell 10A and the pitch at which the first electrode 5 and second electrode 6 serving as rear electrodes are formed on the rear side, and the width of the fluorescent light collector 8 when fabricating the solar cell device 20 according to the first embodiment.

The width of the fluorescent light collector 8 is defined as d, the width of the solar cell device 20 as w, and the repeating pitch of the first electrode 5 and second electrode 6 as p, as illustrated in FIG. 9. The width w is w>d as to the width d. The difference between the width w and width d is w−d≥p/2 as to the repeating pitch p of the first electrode 5 and second electrode 6. That is to say, in order to approach maximal conversion efficiency of the solar cell 10A in a case of providing the fluorescent light collector 8 on the light-receiving face of the solar cell 10A while avoiding the regions Y at both edges at the long sides where the photoelectric conversion properties are lower, it is sufficient for the maximum value dmax of the width d of the fluorescent light collector 8 to be dmax=w−p/2. By satisfying the relation of w−d≥p/2 light can be received at the region of the solar cell 10A where photoelectric conversion properties are not lower, without light collected at the fluorescent light collector 8 leaking, so electricity generating efficiency can be efficiently improved in a limited space.

### (Overview of Fluorescent Light Collecting Solar Cell)

The overview of a common fluorescent light collecting solar cell will be described in brief. A fluorescent light collecting solar cell is a solar cell that has improved light collecting capabilities with regard to external light by a waveguide in which fluorescent substance has been dispersed.

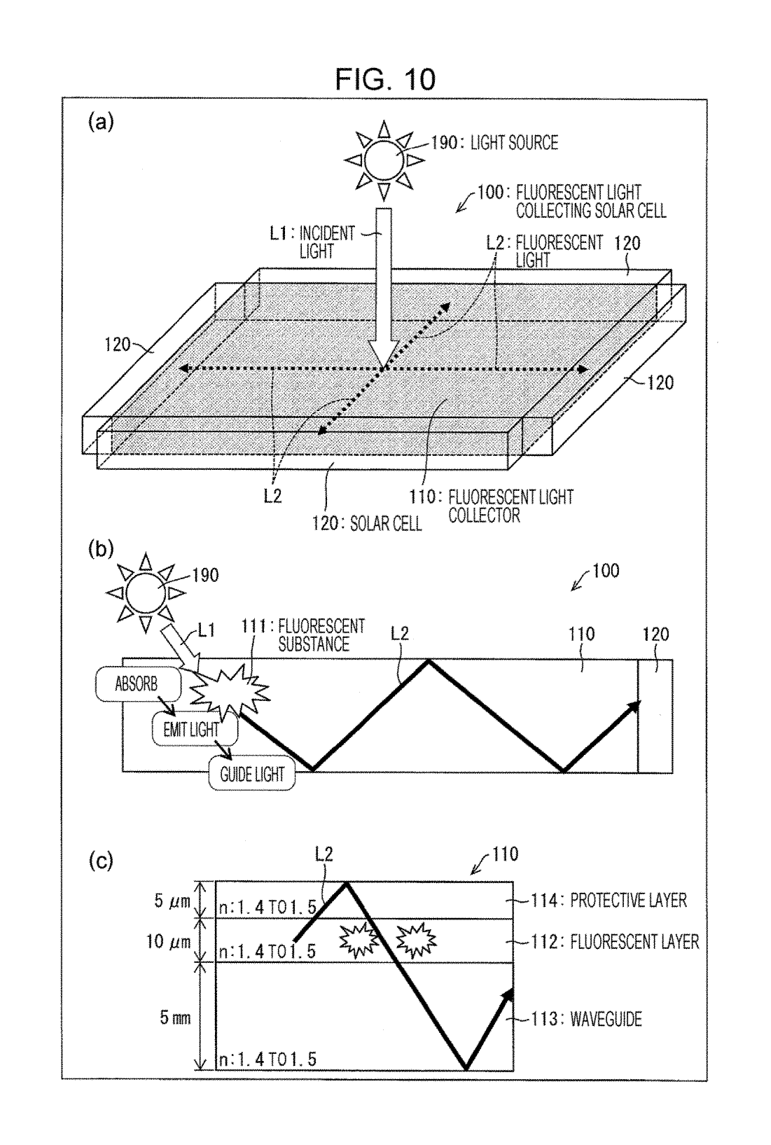

FIG. 10 schematically illustrates the configuration of the fluorescent light collecting solar cell 100, where (a) is a perspective view of the fluorescent light collecting solar cell 100, (b) is a cross-sectional view of the fluorescent light collecting solar cell 100, and (c) is an enlarged cross-sectional view of a fluorescent light collector 110. The fluorescent light collecting solar cell 100 has the fluorescent light collector 110 and a solar cell 120. The fluorescent light collecting solar cell 100 is configured to receive incident light L1 from a light source 190 at the face of the fluorescent light collector 110. Of multiple faces of the fluorescent light collector 110 (six faces in the case of a cuboid shape), the normal of the widest face is preferably directed toward the light source 190 in order to increase the amount of light received by the fluorescent light collecting solar cell 100. For the sake of description, the fluorescent light collector 110 will be described as being a plate-shaped cuboid, with two faces that have a large area being light-receiving faces, and the remaining four side faces being light-emitting faces.

An example in a case where the fluorescent light collecting solar cell 100 is disposed outdoors is exemplified in FIG. 10. Accordingly, the light source 190 is the sun, and the incident light L1 is sunlight. Note however, that the fluorescent light collecting solar cell 100 may be disposed indoors, which will be described later. Accordingly, the light source is not restricted to the sun alone, and may be a lighting device indoors or the like.

The fluorescent light collector 110 has a fluorescent substance 111 that is excited by the incident light L1 dispersed in a transparent resin material that is the base material of the fluorescent light collector 110, as illustrated in (b) in FIG. 10. This fluorescent substance 111 absorbs incident light L1 serving as excitation light, and emits a fluorescent light L2 that has a longer wavelength than the incident light L1, for example. Accordingly, the fluorescent light collector 110 functions as a member that receives the incident light L1 and emits the fluorescent light L2, and as a waveguide that guides the incident light L1 and fluorescent light L2 to one of the four light-emitting faces while subjecting to total reflection at the opposed two light-receiving faces. A known material may be used for the fluorescent substance 111 in accordance with the specifications of the fluorescent light collecting solar cell 100.

The fluorescent light collector 110 has four horizontally-long rectangular side faces, which are light-emitting face, as illustrated in (a) in FIG. 10. Solar cells 120 are disposed at each of the four side faces of the fluorescent light collector 110. Note however, that the shape of the fluorescent light collector 110 is not restricted to a plate-like cuboid, and accordingly the number of side faces does not have to be restricted to four.

The fluorescent light collector 110 is configured to guide the incident light L1 and fluorescent light L2 to each of the four solar cells 120. For example, the fluorescent light collector 110 is made up of a fluorescent layer 112, a waveguide 113, and a protective layer 114, as illustrated in (c) in FIG. 10. The n:1.4 to 1.5 represents that the refractive index is 1.4 to 1.5.

The solar cell 120 is a photoelectric conversion element that converts the energy of the incident light L1 and fluorescent light L2 guided by the fluorescent light collector 110 into electric energy. That is to say, the solar cell 120 receives the incident light L1 and fluorescent light L2 and generates electricity. A known solar cell array can be used as the solar cell 120, but in the case of fabricating the solar cell device 20 according to the present invention, the solar cell 10A, or a solar cell array where multiple solar cells 10A have been connected serially or in parallel, is used.

The fluorescent light collecting solar cell 100 primarily has the following advantages (1) through (4).

(1) The incident light L1 can be received by the fluorescent light collector 110 instead of the solar cells 120. This enables the light-receiving area of the solar cells to be reduced as compared to normal solar cell panels (non-collecting solar cells).

Additional optical members, such as lenses, reflecting mirrors, etc., are not attached other than the above-described fluorescent light collector 110, so a thinner and lighter solar cell can be realized as compared to a collecting solar cell where such additional optical members have been provided.

(2) The incident light L1 can be absorbed by the fluorescent light collector 110 and the fluorescent light L2 can be collected at the solar cells 120, and further, incident light L1 that did not contribute to generating the fluorescent light L2 can be collected at the solar cells 120. Accordingly, even in a case where the incident light L1 does not enter the light-receiving face of the fluorescent light collector 110 approximately perpendicularly, electricity can be generated by the solar cells 120. Thus, dependency of the amount of electricity generated on the incident angle of light entering the light-receiving face can be reduced, even in comparison with collecting solar cells where the above-described additional optical members have been provided.

(3) Incident light can be received at any face of the fluorescent light collector 110. For example, incident light can be received at a second face that is to the opposite face from a first face that receives incident light L1. Thus, incident light can be received at various faces of the fluorescent light collector 110 and electricity can be generated by the solar cells 120, even in comparison with collecting solar cells where the above-described additional optical members have been provided.

(4) Accordingly, the degree of freedom of the shape of the fluorescent light collector 110 can be improved. For example, a spherical fluorescent light collector 110 can be realized, and a curved fluorescent light collector 110 can be realized. Further, changing the shape, such as opening holes or the like in the fluorescent light collector 110, can be performed. In any case, it is sufficient as long as the solar cells 120 are disposed so as to be able to receive incident light L1 and fluorescent light L2 guided by the fluorescent light collector 110.

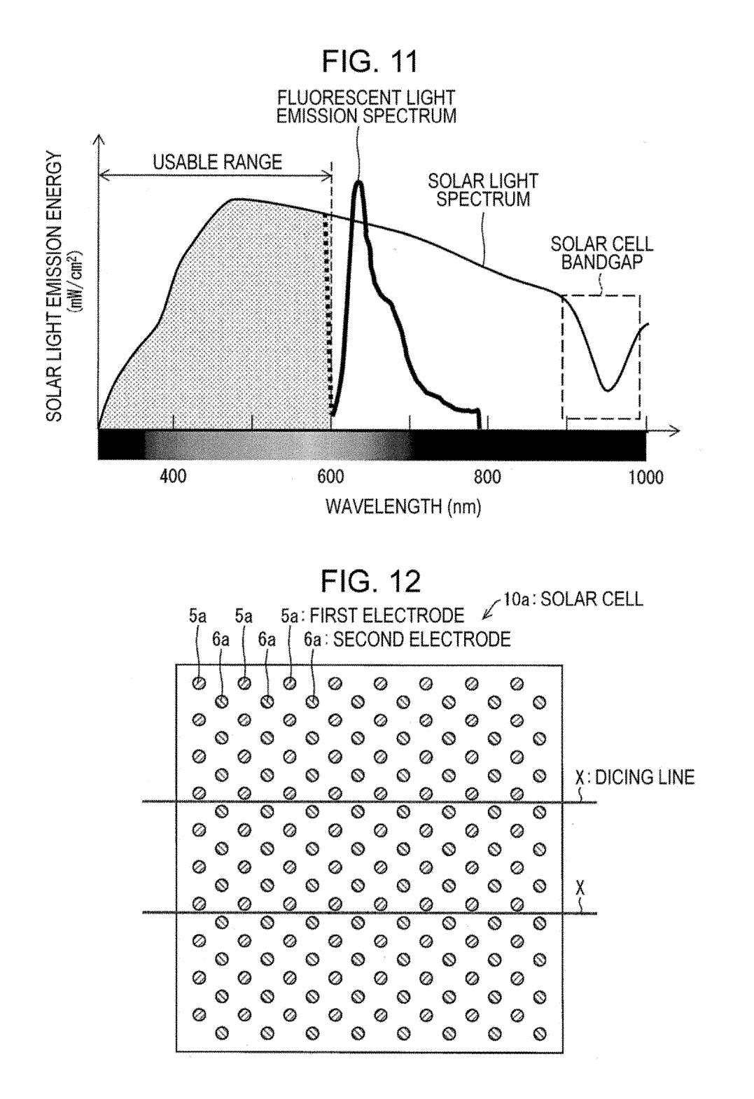

Note that even if the solar cells 120 are irradiated by light of a wavelength having less energy than a bandgap of the solar cells 120, valence band electrons cannot move to the conduction band, so there is no flow of current. Accordingly, the fluorescent substance 111 absorbs the incident light L1, and converts into energy suitable for the bandgap of the solar cells 120, in other words into the fluorescent light L2 having a shorter wavelength than the wavelength corresponding to the bandgap of the solar cells 120, whereby the electricity generating efficiency of the solar cells 120 can be improved. FIG. 11 illustrates an example of a fluorescent light spectrum at the time of converting incident light L1 into fluorescent light L2, illustrating the fluorescent light spectrum in a case of absorbing visible light of 300 to 600 nm, and emitting fluorescent light of 650 nm.

### (Manufacturing Method of Solar Cell Device)

The manufacturing method of the solar cell device 20 that has the solar cell 10 and fluorescent light collector 8 is as follows. When forming the first region 3 made up of a first diffusion layer where a first carrier is generated, and the second region 4 made up of a second diffusion layer where a second carrier that is less than the first carrier is generated, each in band shapes, on the silicon substrate 1, the first region 3 and second region 4 are formed in an alternating manner following a certain direction intersecting the direction in which the first region 3 and second region 4 extend. Next, the first electrode 5 is formed on the first region 3, and the second electrode 6 is formed on the second region 4. Following this, the second region 4 is cut following the extending direction between the first electrode 5 and second electrode 6, thereby fabricating solar cells 10 that are strip-shaped in plain view. Finally, the fluorescent light collector 8 is assembled so that the light-emitting faces face the light-receiving faces of the fabricated solar cells 10.

### Second Embodiment

A second embodiment of the present invention will be described with reference to FIG. 12. FIG. 12 is a plan view schematically illustrating an electrode pattern of a solar cell 10a and dicing lines. The electrode pattern of the solar cell 10a according to the second embodiment is first electrodes 5a and second electrodes 6a formed as dots, as illustrated in FIG. 12.

The first electrodes 5a and second electrodes 6a are each dot shaped and arrayed in rows in a direction following the dicing lines X. The rows of first electrodes 5a and the rows of the second electrodes 6a are formed alternately in the solar cell 10a. As illustrated in FIG. 12, the dicing lines X are set on the second region 4 between the rows of first electrodes 5a and the rows of the second electrodes 6a in the solar cell 10a, so as to dice the solar cell 10a.

The second embodiment according to the present invention is the same as the solar cell device 20 according to the first embodiment of the present invention, except for having changed the electrode pattern of the solar cell 10a to dots.

### Third Embodiment

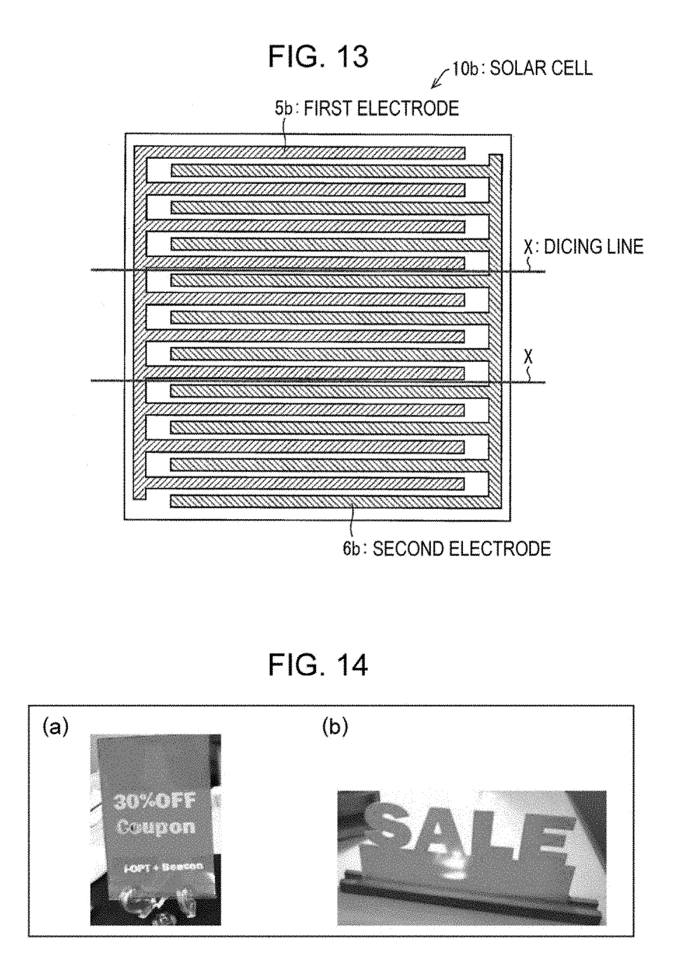

A third embodiment of the present invention will be described with reference to FIG. 13. FIG. 13 is a plan view schematically illustrating an electrode pattern of a solar cell 10b and dicing lines. The electrode pattern of the solar cell 10b according to the third embodiment is first electrodes 5b and second electrodes 6b each having been formed in comb shapes, as illustrated in FIG. 13.

The solar cell 10b has the tooth portions of the comb-shaped first electrode 5b and the tooth portions of the comb-shaped second electrode 6b laid out in an alternating manner. As illustrated in FIG. 13, the dicing lines X are set on the second region 4 between the tooth portions of the first electrode 5a and the tooth portions of the second electrode 6a, so as to dice the solar cell 10b.

The third embodiment according to the present invention is the same as the solar cell device 20 according to the first embodiment of the present invention, except for having changed the electrode pattern of the solar cell 10b to comb shapes.

### Fourth Embodiment

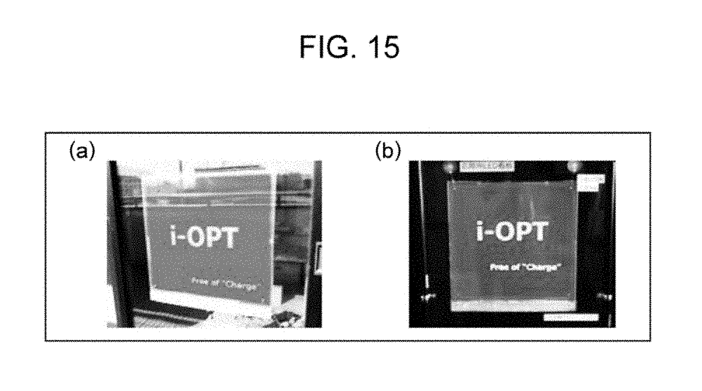

A fourth embodiment of the present invention will be described with reference to FIG. 14 and FIG. 15. In the solar cell device 20 according to the first through third embodiments, the fluorescent light collector 8 may be formed to function as at least part of a point-of-purchase advertisement, and part of the fluorescent light collector 8 may be formed in optional shapes, such as predetermined characters, shapes, symbols, or the like. The fluorescent light collector 8 further does not have to be formed to only represent text, and may be formed to have the shape of cartoon characters, animals, or the like, for example.

FIG. 14 and FIG. 15 illustrate application examples of the solar cell device 20 according to the present embodiment. In FIG. 14, (a) and (b) are images of Beacon POP. In (a) in FIG. 14, a logo is formed on the surface of the fluorescent light collector 8, and in (b) in FIG. 14, part of the fluorescent light collector 8 is formed to represent the text “SALE”. In a case of applying the solar cell device 20 as a Beacon POP (Point of Purchase), fluorescent light is externally emitted from the exposed faces of the fluorescent light collector 8, so the visual effect of the point-of-purchase advertisement can be improved. Also, an advertisement information transmission device attached to the solar cell device 20 can be made to operate on electric power that the solar cell 10A has generated, so as to transmit advertisement information from the point-of-purchase advertisement to mobile terminals of customers. With point-of-purchase advertisements using Beacon POP, part of the light entering the point-of-purchase advertisement will be shielded when the customer brings the mobile terminal close to the advertisement, but the solar cell device 20 according to the present embodiment has the fluorescent light collector 8, so light entering from another direction can be guided to the solar cell 10. As a result, the solar cell device 20 is not readily prevented from generating electricity.

In FIG. 15, (a) and (b) are images of LED signs at day or night. Installing an LED sign having the solar cell device 20 according to the present embodiment in semi-outdoor locations such as by a window, or outdoors, enables the LED sign to be lit regardless of day or night, using electric power generated by the solar cell device 20 during the day time and electric power that has been stored.

Such Beacon POP and LED signs have no need for wiring to obtain electric power from a commercial power source, so the usability as a wiring-free device is high.

### Fifth Embodiment

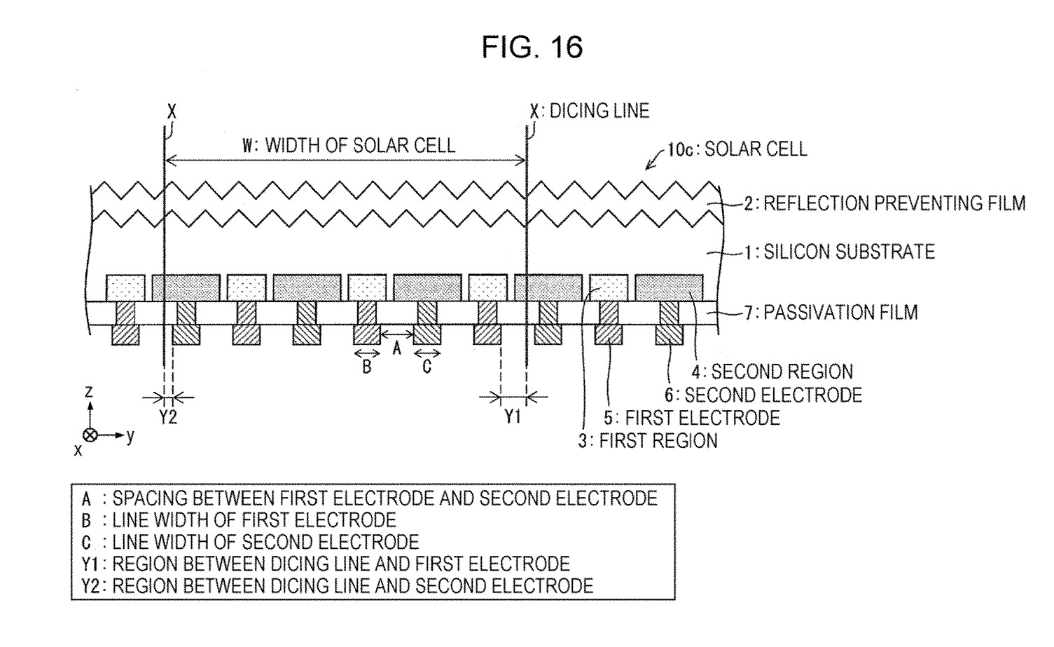

A fifth embodiment of the present invention will be described in detail with reference to FIGS. 16 through 22. For the sake of convenience, members that have the same functions as members described in the above embodiments are denoted with the same symbols, and description thereof will be omitted.

### (Configuration of Solar Cell)

FIG. 16 is a cross-sectional view schematically illustrating the configuration and dicing lines X of a solar cell 10c according to the fifth embodiment of the present invention. In FIG. 17, (a) is a plan view schematically illustrating the positional relation between dicing lines X and regions Y that are regions with lower properties that occur in the solar cell 10c, and (b) in FIG. 17 is a cross-sectional view schematically illustrating a cut face after cutting the solar cell 10c illustrated in (a) in FIG. 17 following the dicing lines X.

As illustrated in FIG. 16, a great number of first regions 3 and first electrodes 5, and a great number of second regions 4 and second electrodes 6 are arrayed in an alternating manner in the solar cell 10c, following the y direction (second direction, width direction). The multiple dicing lines X for cutting out strip-shaped solar cells from the solar cell 10c are all set so as to cut the second regions 4. This is because it is preferable to having the second region exposed at the cut faces on both ends in the width of the strip-shaped solar cells, but solar cells with the first region exposed at the cut faces may be used as well.

Further, the dicing lines X according to the present embodiment are set such that an odd number (e.g., three) first electrodes 5 and an odd number (e.g., three) second electrodes 6 fit between two adjacent dicing lines X. In a case of setting the dicing lines X in this way, multiple strip-shaped solar cells 10C having an even number (e.g., six) total of first electrodes 5 and second electrodes 6 can be cut out from the solar cell 10c, as illustrated in (a) in FIG. 17.

Note that the spacing between the two adjacent dicing lines X regulates the width w of the solar cells 10c cut out.

Setting the dicing lines X in this way exposes the second region 4 at the cut face formed on both ends in the width of the strip-shaped solar cells 10C as illustrated in (b) in FIG. 17. A side L1 situated at the upper edge of the silicon substrate 1 exposed at one cut face out of the cut faces at both ends, and a side L2 situated at the upper edge of the silicon substrate 1 exposed at the other cut face, will be considered. In this case, the side L1 and the side L2 correspond to the two sides on the quadrangle silicon substrate 1 having at least two side parallel to the x direction (first direction, longitudinal direction).

Configurations other than the above described in the solar cell 10c are the same as the solar cell 10 described in the first embodiment.

### (Cutting Margin)

The multiple first electrodes 5 and the multiple second electrodes 6 each have side faces following the z direction (thickness direction), as illustrated in FIG. 16. Of these side faces, side faces facing imaginary planes where the cut faces have been extended have margins (spaces) as to the imaginary planes. The imaginary planes are equivalent to the dicing lines X understood to be planes.

At one end side of the width w of the solar cell 10C, a region Y2 is set as a margin between the side face of the second electrode 6 facing the imaginary plane and the imaginary plane, i.e., the dicing line X, as illustrated in FIG. 16. On the other hand, at the other end side of the width w, a region Y1 is set as a margin between the side face of the first electrode 5 facing the imaginary plane and the imaginary plane, i.e., the dicing line X. If the spacing between the first electrode 5 and second electrode 6 is represented by A, and the width of the regions Y1 and Y2 are represented by Y1 and Y2, the relation between the width Y1 and Y2 and spacing A is 0<Y1<A and 0<Y2<A. In a case where the spacing A is set to a set value, and the first electrodes 5 and second electrodes 6 are disposed in an alternating manner in the y direction, Y1+Y2=A preferably holds for all solar cells 10C cut out. However, taking variance in dicing into consideration, Y1+Y2≈A holds.

Thus, securing a margin between the dicing lines X and first electrode 5 and second electrode 6 enables the first electrode 5 and second electrode 6 not to be cut, so a suitable solar cell 10C with the first electrode 5 and second electrode 6 not exposed at cut faces can be obtained.

(Advantages of the Total Number of Electrodes being an Even Number)

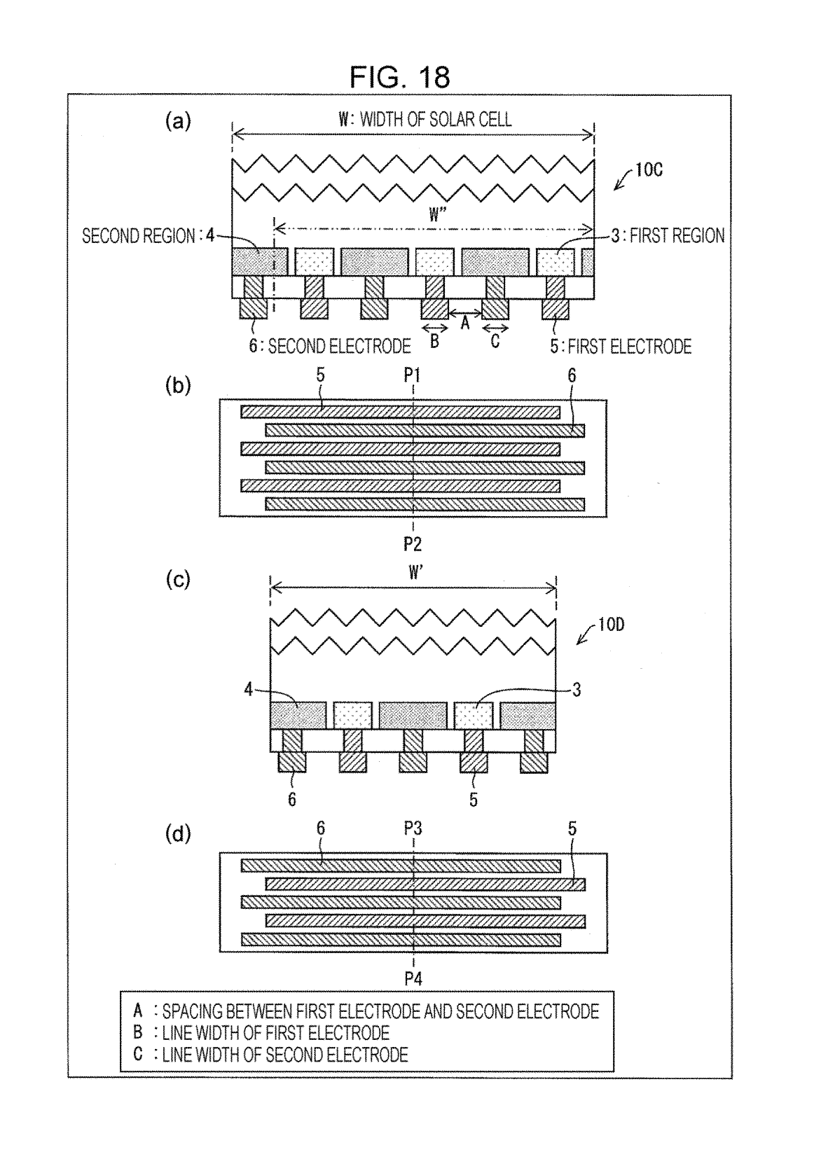

FIG. 18 illustrates a strip-shaped solar cell according to the fifth embodiment of the present invention, where (a) and (b) are a cross-sectional view and plan view schematically illustrating electrode patterns thereof, and (c) and (d) are a cross-sectional view and plan view schematically illustrating electrode patterns of a strip-shaped solar cell according to a sixth embodiment of the present invention for comparison. Note that (a) in FIG. 18 is an enlarged view of a cross-section taken along line P1-P2 in (b) in FIG. 18, and (c) in FIG. 18 is an enlarged view of a cross-section taken along line P3-P4 in (d) in FIG. 18.

As illustrated in FIG. 16 and FIG. 17, setting all dicing lines X so that the total number of first electrodes 5 and second electrodes 6 is an even number results in the way that the first electrodes 5 and second electrodes 6 are laid out in the multiple solar cells 10C cut out being the same. That is to say, a second electrode 6 is situated at one end side of the both ends in the width w of the solar cell 10C, and a first electrode 5 is situated at the other end side, as illustrated in (a) and (b) in FIG. 18. Thus, in a case where the total number of first electrodes 5 and second electrodes 6 is an even number is preferably, since a great number of strip-shaped solar cells 10C where the way that the first electrodes 5 and second electrodes 6 are laid out is the same.

(Case where Total Number of Electrodes is Odd Number)

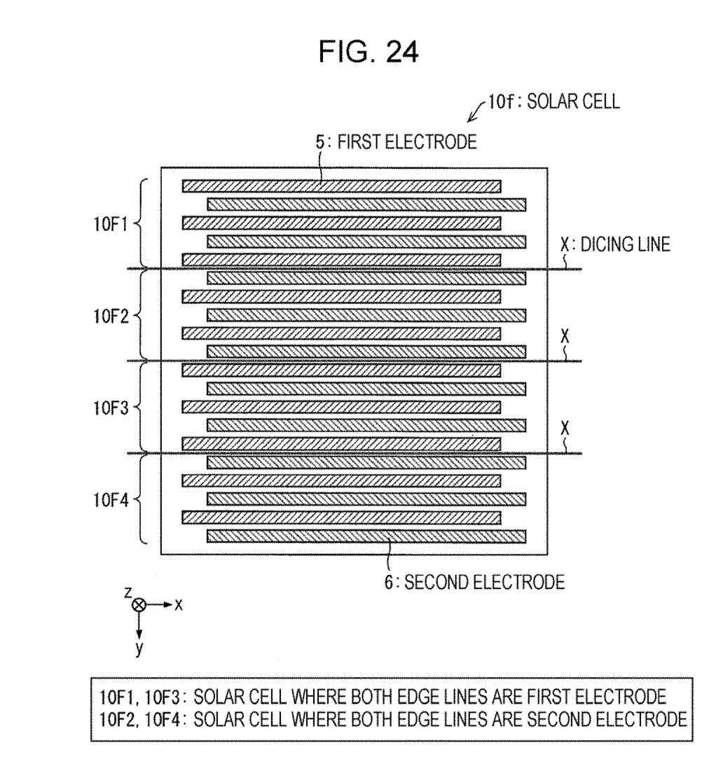

On the other hand, setting all dicing lines X so that the total number of first electrodes 5 and second electrodes 6 is an odd number yields two ways (electrode patterns) that the first electrodes 5 and second electrodes 6 are laid out. The first of the two electrode patterns is one where second electrodes 6 are situated on both ends in the width w′ of the solar cell 10D, as illustrated in (c) and (d) in FIG. 18. This is also illustrated as solar cells 10F2 and 10F4 in the later-described FIG. 24. The second of the two electrode patterns is one where first electrodes 5 are situated on both ends in the width w′ of the solar cell 10D, illustrated as solar cells 10F1 and 10F3 in the later-described FIG. 24.

Further, in a case of setting the spacing A to a set value, i.e., in a case of disposing the first electrodes 5 and second electrodes 6 equidistantly following the y direction (width direction), there are also two patterns in the width of the solar cells 10D cut out in accordance with the two electrode patterns. It can be seen from comparing a case where second electrodes 6 are situated on both ends in the width w′ of the solar cell 10D, as illustrated in (c) in FIG. 18, with a case where first electrode 5 are situated on both ends in the width w″ of the solar cell 10D, as illustrated by an imaginary line in (a) in FIG. 18, that w′<w″. The reason is that in a case where the first electrodes 5 are situated on both ends in the width w″ of the solar cell 10D, the width of the solar cell 10D becomes broader in accordance with having to cut the second region adjacent to the outer side of the first electrodes 5 at both ends.

A way of obtaining solar cells 10D of the same width in a case of setting the total number of first electrodes 5 and second electrodes 6 to be an odd number will be described in a later-described sixth embodiment.

### (Configuration of Solar Cell Device)

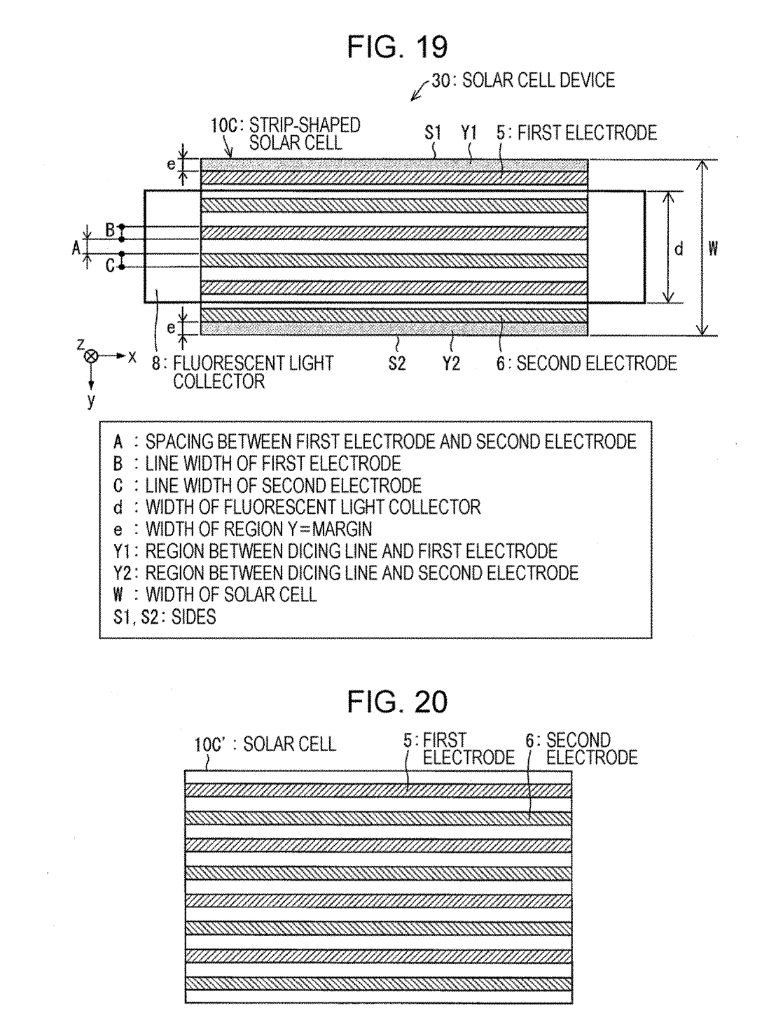

Next, a solar cell device 30 according to the present fifth embodiment will be described. FIG. 19 is a plan view schematically illustrating the configuration of the solar cell device 30 according to the present fifth embodiment. The solar cell device 30 has the solar cell 10C and fluorescent light collector 8 assembled so that the light-receiving face of the strip-shaped solar cell 10C and the light-emitting face of the fluorescent light collector 8 face each other, as illustrated in FIG. 19.

The trick when assembling the fluorescent light collector 8 to the solar cell 10C is to appropriately set the relation between the width w of the solar cell 10C and the width d of the fluorescent light collector 8. That is to say, a condition required for the width d of the fluorescent light collector 8 is (i) that the fluorescent light collector 8 does not overlap region Y1 and region Y2 that are regions with lower properties that occur at both end portions in the width of the solar cell 10C. As for more preferable conditions, this is (ii) that at the time of assembling the fluorescent light collector 8 to the solar cell 10C a margin is secured to where the fluorescent light collector 8 does not overlap region Y1 and region Y2 even if there is positional deviation of the fluorescent light collector 8.

Note that the fact that the regions with lower properties occur along the dicing lines X illustrated in FIG. 17, i.e., following the long sides of the solar cell 10C near the cut face of the solar cell 10C has already been described with reference to FIG. 6.

### (Way 1 of Setting Margin)

The spacing between the first electrode 5 and second electrode 6 is set to A (e.g., 0.5 mm), the width of the first electrode 5 to B (e.g., 0.1 mm), and the width of the second electrode 6 to C (e.g., 0.1 mm), as illustrated in FIG. 18 and FIG. 19. The width of the region Y1 and region Y2 is e, as illustrated in FIG. 19. The direction in which the widths extend following the y direction.

From the perspective of satisfying the above-described condition (i), the relation between the width w of the solar cell 10C and the width d of the fluorescent light collector 8 is sufficient to be d<w and 2e≤w−d. 2e≤w−d can also be expressed as d≤w−2e. Further, 2e≤A is preferable, which will be described below, so d≤w−2e can be expressed as

d≤w−A. Expression 1

Now, the reason why 2e≤A is preferable will be described. In FIG. 16, the positions of the two adjacent dicing lines X are slightly shifted, in a space between the first electrode 5 and second electrode 6, in the y direction from the center of the space. However, it can be seen that in a case where the positions of the dicing lines X agree with the center of the space between the first electrode 5 and second electrode 6, the total of the width of region Y1 and the width of region Y2 is equal to the spacing A. Accordingly, the positions of the dicing lines X theoretically should be decided so that 2e=A. However, when taking into consideration reduction in width due to cutting, positional deviation of the dicing lines X, and so forth in actual manufacturing, then setting the positions of the dicing lines X to satisfy 2e≤A with a margin secured so that the first electrode 5 or second electrode 6 is not cut, can be said to be preferable.

Thus, setting the width d of the fluorescent light collector 8 so that d≤w−A avoids the light-emitting face of the fluorescent light collector 8 from having an unnecessary width that would overlap the region Y1 and region Y2 of which photoelectric conversion properties have deteriorated. Also, light that has entered the fluorescent light collector 8 can be guided to regions of the solar cell 10C where photoelectric conversion properties have not decreased, so the solar cell 10C can efficiently have improved electricity generating efficiency with a limited area.

### (Way 2 of Setting Margin)

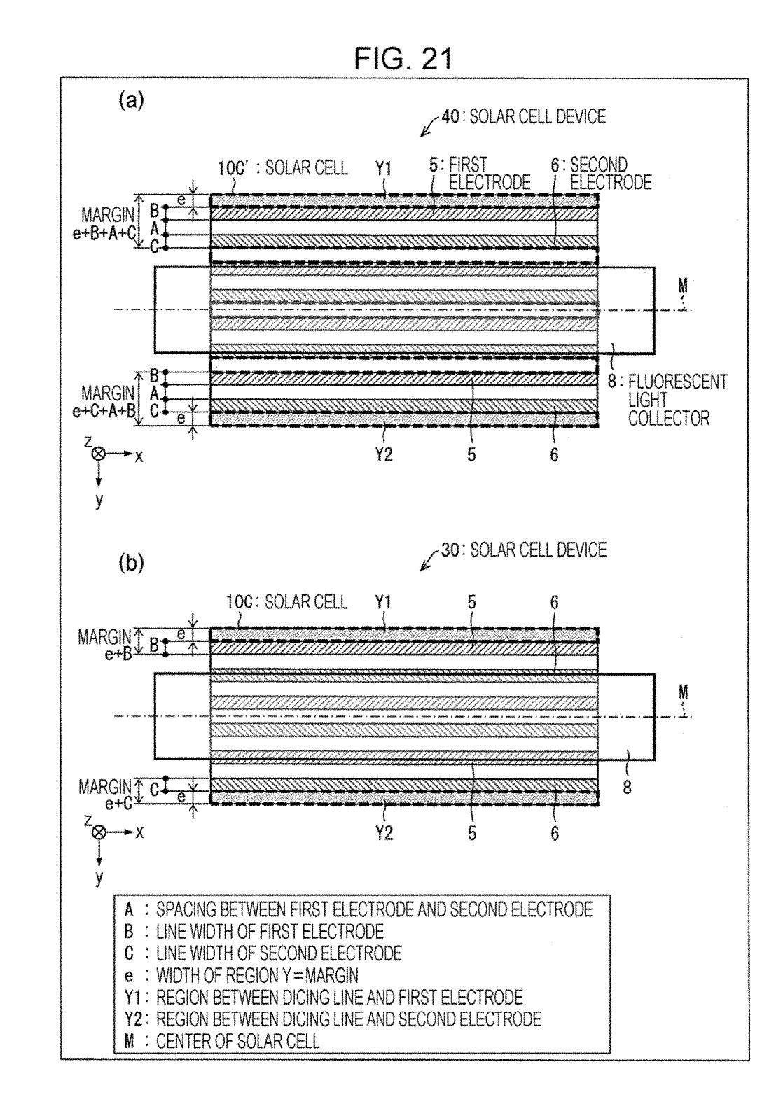

(a) and (b) in FIG. 21 are plan views illustrating two examples, as setting examples of a margin when assembling the fluorescent light collector 8 to the strip-shaped solar cell 10C or 10C′ according to the fifth embodiment.

The relation between the width w of the solar cell 10C and the width d of the fluorescent light collector 8 is preferably set to d≤w−A−B or d≤w−A−C from the perspective of satisfying the above-described condition (ii), and is even more preferably set to

d≤w−A−B−C. Expression 2

The reason thereof is as follows.

The first electrode 5 that has the width B is adjacent to the region Y1, and the second electrode 6 that has the width C is adjacent to the region Y2 in the solar cell device 30, as illustrated in (b) in FIG. 21. Including leeway equivalent to these width B and/or width C in the margin enables the margin to have leeway so that the fluorescent light collector 8 does not overlap the region Y1 and/or region Y2, even if positional deviation of the fluorescent light collector 8 does occur.

### (Way 3 of Setting Margin)

The relation between the width w of the solar cell 10C and the width d of the fluorescent light collector 8 is further preferably set to

d≤w−3A−2B−2C Expression 3

from the perspective of satisfying the above-described condition (ii). However, setting the width d of the fluorescent light collector 8 to be too narrow as to the width w of the solar cell 10C is detrimental to increasing the electricity generating efficiency. Accordingly, increasing the total number of first electrodes 5 and second electrodes 6 to increase the width w of the solar cell 10C facilitates securing the width d of the fluorescent light collector 8 where d≤w−3A−2B−2C.

For example, the solar cell 10C′ making up a solar cell device 40 has one each of the first electrode 5 and second electrode 6 increased as compared to the solar cell 10C, for a total of eight, as illustrated in FIG. 20 and (a) in FIG. 21.

In the case of the solar cell 10C′, a margin is secured such that one each of the first electrode 5 and second electrode 6 is present between the region Y1 and the fluorescent light collector 8, as illustrated in (a) in FIG. 21. A margin is also secured such that one each of the first electrode 5 and second electrode 6 is present between the region Y2 and the fluorescent light collector 8.

Accordingly, it is good to use the width e of the region Y1, and secure e+B+A+C as the margin of the region Y1 side. Alternatively, it is good to use the width e of the region Y2, and secure e+C+A+B as the margin of the region Y2 side. Thus, with e=A/2, it can be said to be preferable to set d≤w−3A/2−B−C in order to at least secure a margin for one side worth.

Further, since it is even more preferable to secure margins for both the region Y1 side and region Y2 side, it can be said to be preferable to set the width d of the fluorescent light collector 8 so that d≤w−3A/2−B−C−3A/2−B−C=w−3A−2B−2C. This leads to the above Expression 3.

### (Discussion Relating to Positional Deviation of Fluorescent Light Collector 8)

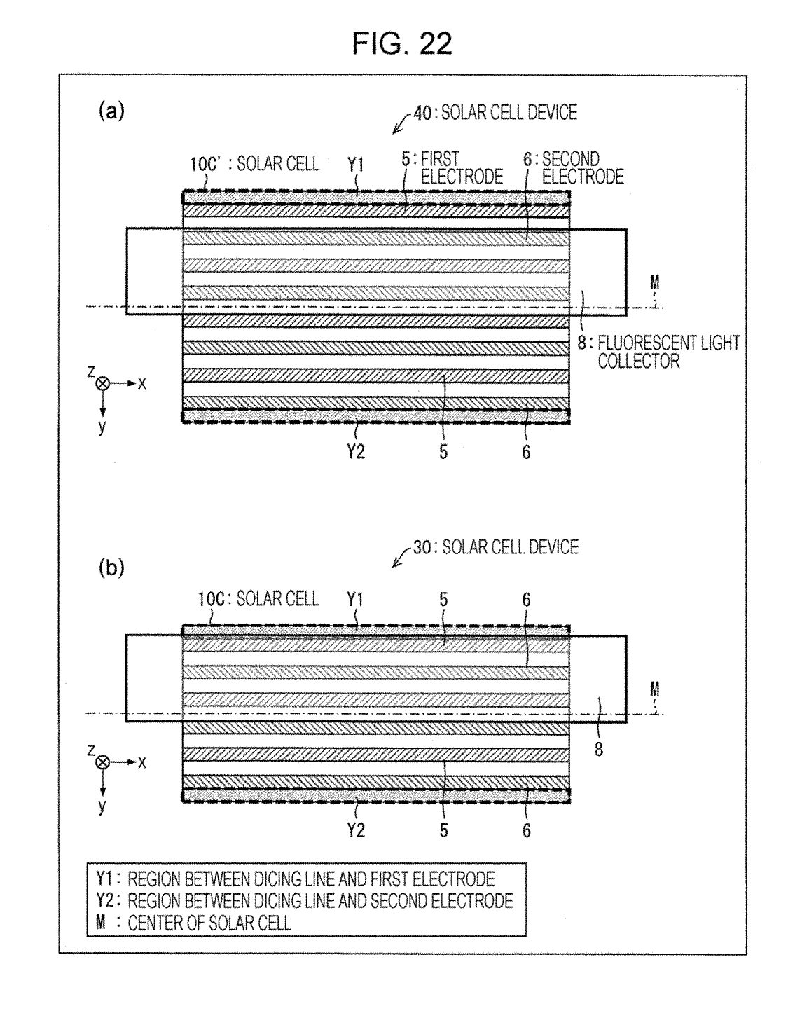

In FIG. 22, (a) and (b) are plan views schematically illustrating examples of positional deviation when assembling the light collector to the strip-shaped solar cell according to the fifth embodiment, corresponding to (a) and (b) in FIG. 21. (a) in FIG. 22 illustrates a state where positional deviation generally equivalent to two electrodes has occurred when the fluorescent light collector 8 is assembled to the solar cell 10C′ of which the total number of electrodes is eight. Also, (b) in FIG. 22 illustrates a state where positional deviation of the same amount has occurred when the fluorescent light collector 8 is assembled to the solar cell 10C of which the total number of electrodes is six.

On the other hand, (a) in FIG. 21 illustrates a state where no positional deviation has occurred when assembling the fluorescent light collector 8 to the solar cell 10C′. That is to say, a state is illustrated in which a center line M passing through the center of the width w of the solar cell 10C′ and extending in the x direction (first direction, longitudinal direction) and a center line passing through the center of the width d of the fluorescent light collector 8 and extending in the x direction (first direction, longitudinal direction) match. Also, (b) in FIG. 21 illustrates a state the same as above where no positional deviation has occurred when assembling the fluorescent light collector 8 to the solar cell 10C.

Comparing (a) and (b) in FIG. 22, the solar cell 10C′ of which the number of electrodes is eight, has a greater width of the solar cell than the solar cell 10C of which the number of electrodes is six. Accordingly, the probability of the light-emitting face thereof overlapping the regions Y1 or Y2 where photoelectric conversion properties are lower due to positional deviation of the fluorescent light collector 8 is lower for the solar cell 10C′ than the solar cell 10C. Also, even though positional deviation of the fluorescent light collector 8 occurs, the light-emitting face of the fluorescent light collector 8 does not overlap the region Y1 at the one side in the width of the solar cell 10C′, as illustrated in (a) in FIG. 22. Conversely, in a case where the same amount of positional deviation of the fluorescent light collector 8 occurs as to the solar cell 10C, the light-emitting face of the fluorescent light collector 8 overlaps the region Y1 at the one side in the width of the solar cell 10C, as illustrated in (b) in FIG. 22. Loss occurs in light guided to the region where properties are lower when the light-emitting face of the fluorescent light collector 8 overlaps the region where properties are lower, so light-emitting efficiency of the solar cell is lower.

Thus, increasing the number of electrodes in the y direction (width direction) of a strip-shaped solar cell yields an advantage in that lower output does not readily occur even if positional deviation occurs when applying the fluorescent light collector to the strip-shaped solar cell, as compared to a solar cell with fewer electrodes.

### Sixth Embodiment

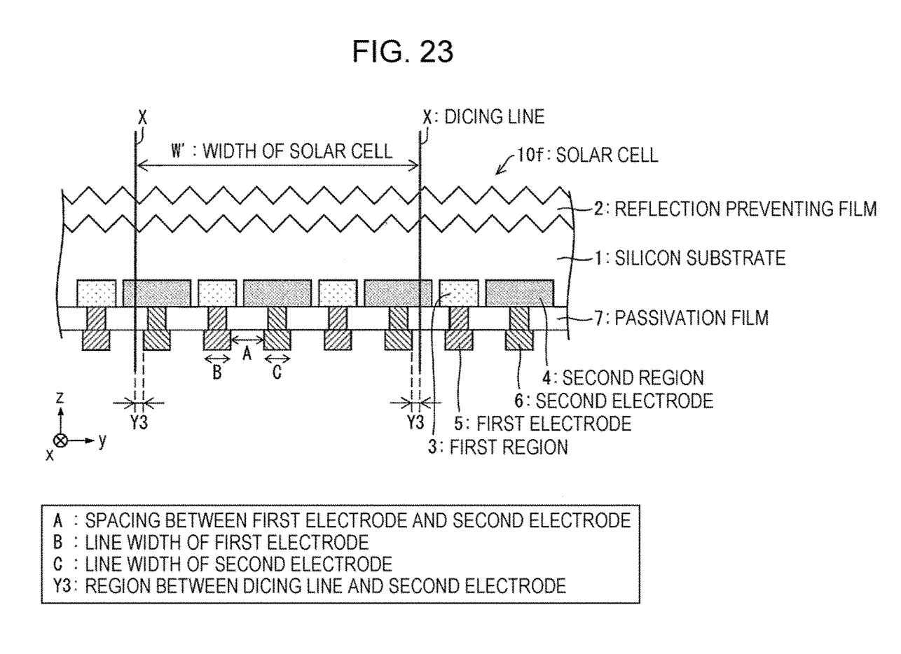

A sixth embodiment of the present invention will be described in detail with reference to FIGS. 23 through 29. For the sake of convenience, members that have the same functions as members described in the above embodiments are denoted with the same symbols, and description thereof will be omitted.

### (Configuration of Solar Cell)

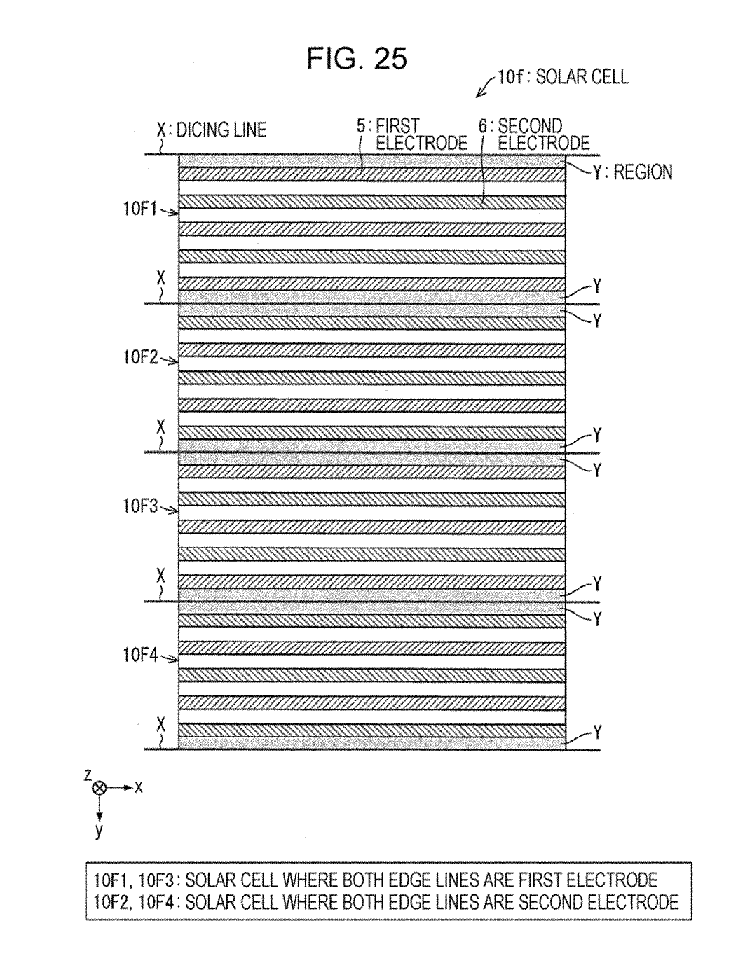

FIG. 23 is a cross-sectional view schematically illustrating the configuration and dicing lines X of a solar cell 10f according to the sixth embodiment of the present invention. FIG. 24 is a plan view schematically illustrating the electrode pattern and dicing lines X of the solar cell f according to the sixth embodiment of the present invention. FIG. 25 is a plan view schematically illustrating the positional relation between dicing lines X and regions Y that are regions with lower properties in the solar cell 10f.

As illustrated in FIG. 23, a great number of first regions 3 and first electrodes 5, and a great number of second regions 4 and second electrodes 6 are arrayed in an alternating manner in the solar cell 10f, following the y direction. The multiple dicing lines X for cutting out strip-shaped solar cells from the solar cell 10f are all set so as to cut the second regions 4. Also, the dicing lines X according to the present embodiment are set such that an odd number (e.g., five) of the total of first electrodes 5 and second electrodes 6 fit between two adjacent dicing lines X. As a result, solar cells 10F1 through 10F4 are cut out from the solar cell 10f as multiple strip-shaped solar cells, as illustrated in FIG. 24 and FIG. 25.

Configurations other than the above described in the solar cell 10f are the same as the solar cell 10 described in the first embodiment.

### (Electrode Patterns)

As described earlier, setting all dicing lines X such that the total number of first electrodes 5 and second electrodes 6 is an odd number gives two ways in which the first electrode 5 and second electrode 6 are laid out (electrode patterns), and the two electrode patterns appear alternately following the y direction. That is to say, the first electrode 5 is situated at both ends in the width of the solar cells 10F1 and 10F3, while the second electrode 6 is situated at both ends in the width of the solar cells 10F2 and 10F4, as illustrated in FIG. 24. Also, the regions Y which are regions where properties are lower occur near the cut face of the solar cells 10F1 through 10F4 along the dicing lines X illustrated in FIG. 25, in the same way as in the above-described embodiments.

Further, description has been made with reference to (a) and (c) in FIG. 18 that there are two widths of solar cells cut out in a case of setting the spacing A between the first electrodes 5 and second electrodes 6 to a set value, in accordance with the two electrode patterns.

Now, a way of yielding solar cells 10F1 through 10F4 having the same width in a case of setting the total number of first electrodes 5 and second electrodes 6 to an odd number will be described. Specifically, the spacing A between the first electrodes 5 and second electrodes 6 is not set to a set value. For example, as illustrated in FIG. 25, the spacing between the first electrode 5 and second electrode 6 on either side of each dicing line X is set wider than the spacing A. In addition, with width of the second region 4 that is to be cut is set wider in conjunction with increasing the spacing between the first electrode 5 and second electrode 6.

Accordingly, the width of the solar cells 10F1 through 10F4 can be made to be equal, as illustrated in FIG. 25. The width of the second region 4 to be cut is also set wider, so the accuracy of cutting the second region 4 can be improved even if there is positional deviation of the dicing lines X.

### (Way 1 of Setting Margin)

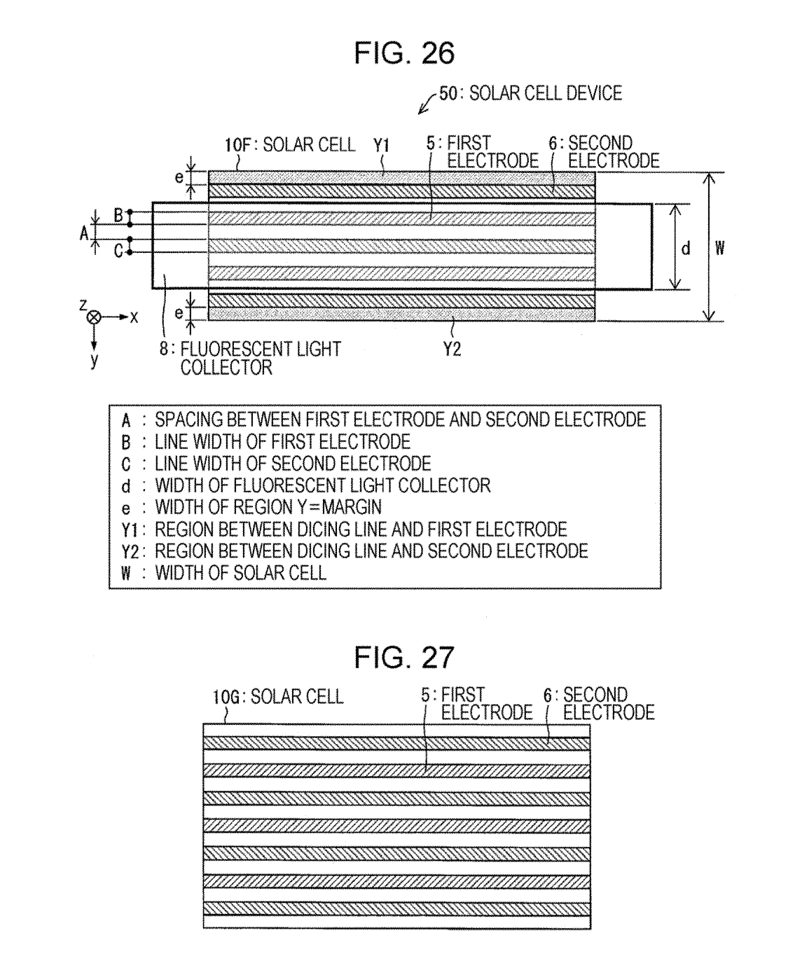

The region Y1 and region Y2 which are regions where properties are lower are formed at both ends in the width direction with the solar cell 10F where the total number of first electrodes 5 and second electrodes 6 is set to be an odd number, in the same way as the solar cell 10C illustrated in FIG. 19, as illustrated in the solar cell device 50 in FIG. 26.

Accordingly, setting the width d of the fluorescent light collector 8 as to the width w of the solar cell 10F so that d≤w−A (aforementioned Expression 1), in the same way as with the solar cell 10C, avoids the light-emitting face of the fluorescent light collector 8 from having an unnecessary width that would overlap the region Y1 and region Y2 of which photoelectric conversion properties have deteriorated.

### (Way 2 of Setting Margin)

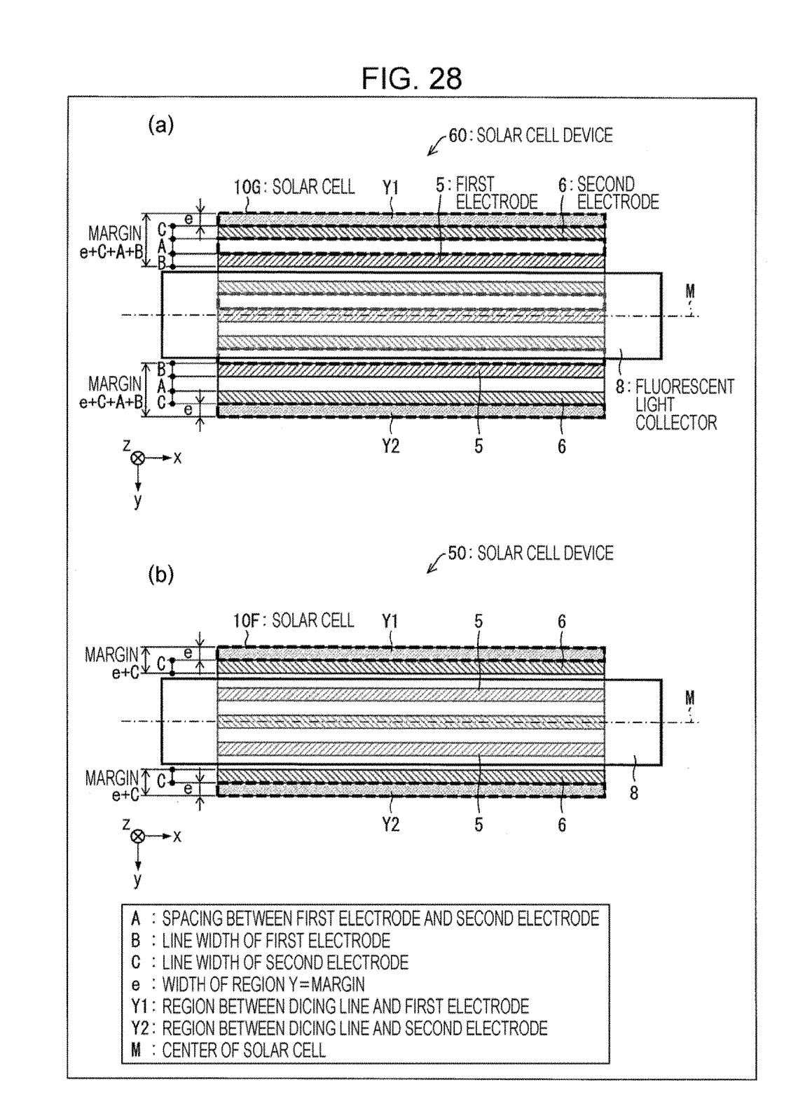

In FIG. 28, (a) and (b) are plan views schematically illustrating two examples, as setting examples of a margin when assembling the fluorescent light collector 8 to the strip-shaped solar cell 10F or 10G according to the sixth embodiment. Note that the solar cells 10F and 10G have configurations where one second electrode 6 each is situated at both ends in the width.

In this case, the relation between the width w of the solar cell 10F and the width d of the fluorescent light collector 8 is preferably set to d≤w−A−C from the perspective of satisfying the above-described condition (ii), and is even more preferably set to

d≤w−A−2C. Expression 4

The reason thereof is as follows.

The second electrode 6 that has the width C is adjacent to the region Y1, and the second electrode 6 that has the width C is also adjacent to the region Y2, as illustrated in (b) in FIG. 28. Including leeway equivalent to at least one of these two widths C in the margin is preferable, and including leeway equivalent to both of these two widths C in the margin is even more preferable. Accordingly, this enables the margin to have leeway so that even if there is positional deviation of the fluorescent light collector 8, the fluorescent light collector 8 does not overlap the region Y1 and/or region Y2.

### (Way 3 of Setting Margin)

The relation between the width w of the solar cell 10F and the width d of the fluorescent light collector 8 is further preferably set to d≤w−3A−2B−2C (aforementioned Expression 3) from the perspective of satisfying the above-described condition (ii). However, increasing the total number of first electrodes 5 and second electrodes 6 to increase the width w of the solar cell 10F facilitates securing the width d of the fluorescent light collector 8 where d≤w−3A−2B−2C, which has been described above.

For example, the solar cell 10G making up a solar cell device 60 has one each of the first electrode 5 and second electrode 6 increased as compared to the solar cell 10F, for a total of seven, as illustrated in FIG. 27 and (a) in FIG. 28.

In the case of the solar cell 10G, a margin is secured such that one each of the first electrode 5 and second electrode 6 is present between the region Y1 and the fluorescent light collector 8, as illustrated in (a) in FIG. 28. A margin is also secured such that one each of the first electrode 5 and second electrode 6 is present between the region Y2 and the fluorescent light collector 8. The way in which the margin is secured is the same as with the solar cell 10C′ illustrated in (a) in FIG. 21. Accordingly, it is preferable to set the width d of the fluorescent light collector 8 to d≤w−3A/2−B−C in the same way as with the solar cell 10C′, and further preferable to set the width d of the fluorescent light collector 8 to d≤w−3A−2B−2C.

### (Discussion Relating to Positional Deviation of Fluorescent Light Collector 8)

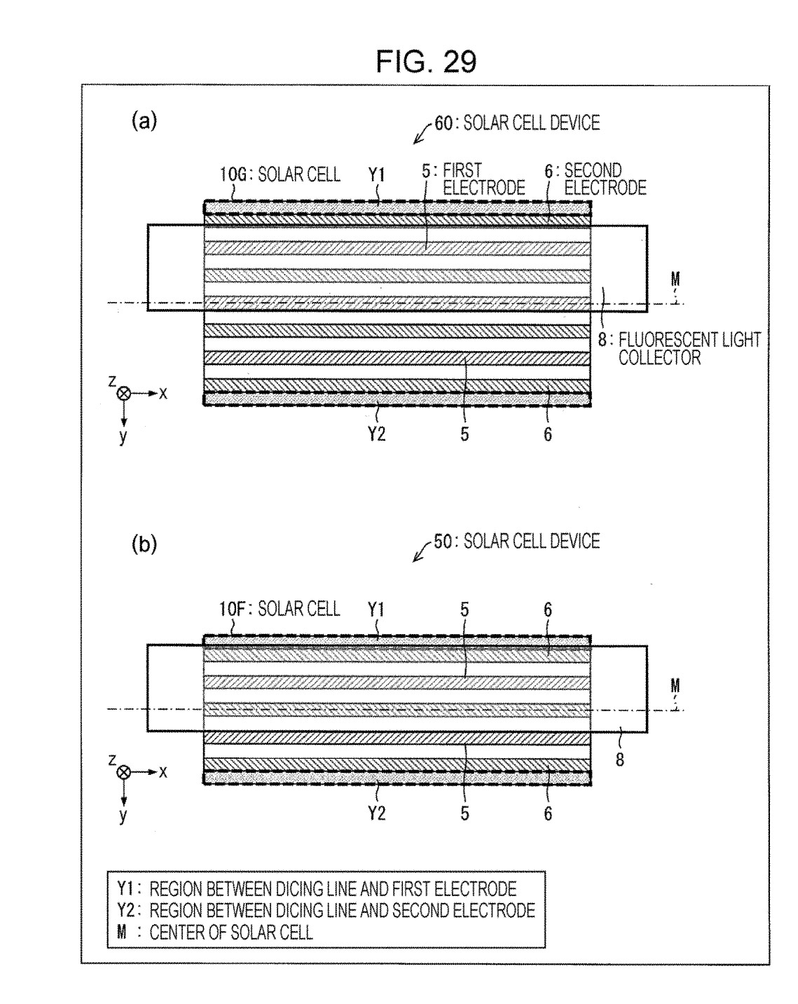

In FIG. 29, (a) and (b) are plan views schematically illustrating examples of positional deviation when assembling the light collector to the strip-shaped solar cell according to the sixth embodiment, corresponding to (a) and (b) in FIG. 28. (a) in FIG. 29 illustrates a state where positional deviation generally equivalent to 1.5 electrodes worth has occurred when the fluorescent light collector 8 is assembled to the solar cell 10G of which the total number of electrodes is seven. Also, (b) in FIG. 29 illustrates a state where positional deviation of the same amount has occurred when the fluorescent light collector 8 is assembled to the solar cell 10F of which the total number of electrodes is five.

On the other hand, (a) in FIG. 28 illustrates a state where no positional deviation has occurred when assembling the fluorescent light collector 8 to the solar cell 10G. That is to say, a state is illustrated in which a center line M passing through the center of the width w of the solar cell 10F and extending in the x direction (first direction, longitudinal direction) and a center line passing through the center of the width d of the fluorescent light collector 8 and extending in the x direction (first direction, longitudinal direction) match. Also, (b) in FIG. 28 illustrates a state the same as above where no positional deviation has occurred when assembling the fluorescent light collector 8 to the solar cell 10F.

Comparing (a) and (b) in FIG. 29, the solar cell 10G of which the number of electrodes is seven, has a greater width of the solar cell than the solar cell 10F of which the number of electrodes is five. Accordingly, the probability of the light-emitting face thereof overlapping the regions Y1 or Y2 where photoelectric conversion properties are lower due to positional deviation of the fluorescent light collector 8 is lower for the solar cell 10G than the solar cell 10F. Actually, even though positional deviation of the fluorescent light collector 8 occurs, the light-emitting face of the fluorescent light collector 8 does not overlap the region Y1 at the one end side in the width of the solar cell 10G, as illustrated in (a) in FIG. 29. Conversely, in a case where positional deviation of the fluorescent light collector 8 occurs as to the solar cell 10F, the light-emitting face of the fluorescent light collector 8 overlaps the region Y1 of the solar cell 10F, as illustrated in (b) in FIG. 29.

Thus, increasing the number of electrodes in the y direction (width direction) of a strip-shaped solar cell yields an advantage in that lower output does not readily occur even if positional deviation occurs when applying the fluorescent light collector to the strip-shaped solar cell, as compared to a solar cell with fewer electrodes, regardless of whether the total number of electrodes is even or odd.

### Seventh Embodiment

In the above first through sixth embodiments, a light collector that guides incident light to a light-emitting face while subjecting to total reflection at two opposed light-receiving faces has been employed as the light collecting member having light-emitting faces facing light-receiving faces of solar cells. A fluorescent substance is dispersed in a transparent resin material that is the base material of the light collector, to improve the electricity generating efficiency of the solar cells.

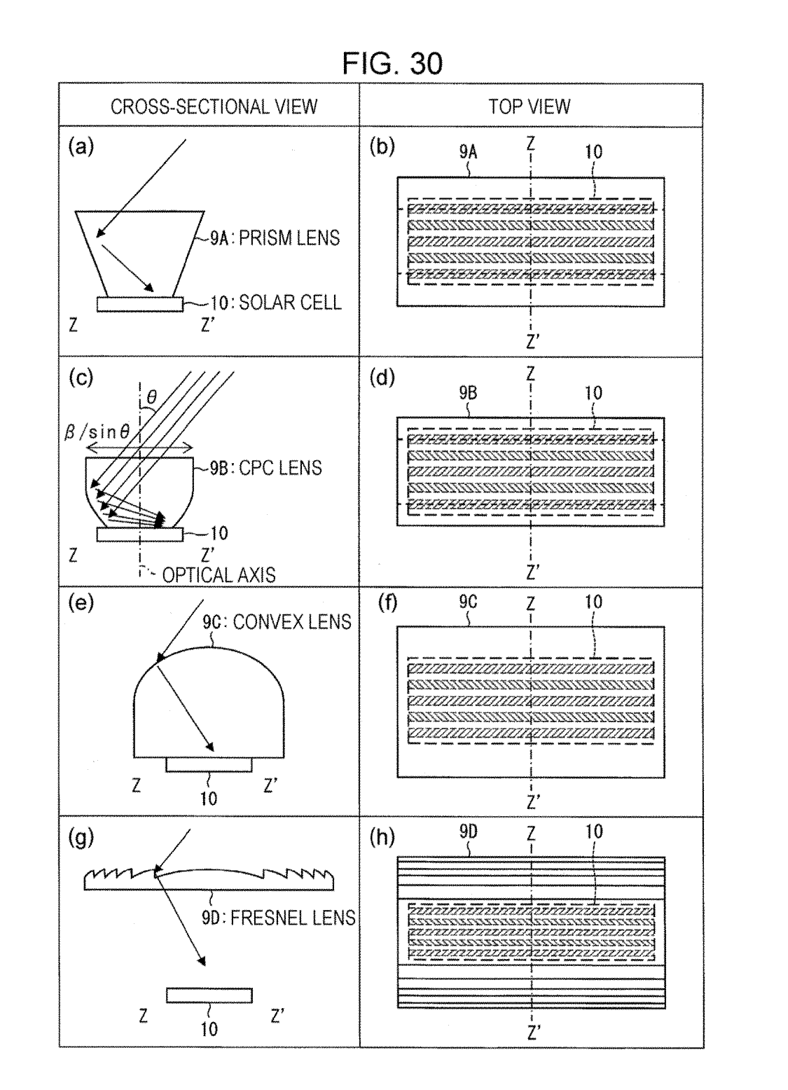

In the present embodiment, an optical element having the functions of a condenser lens is employed as the light collecting member, instead of the light collector or fluorescent light collector. FIG. 30 (a) through (h) are cross-sectional views and top views explanatorily illustrating four examples of solar cell devices where the optical elements have been assembled to solar cells as light collecting members. The cross-sectional view illustrates cross-sections of the solar cell devices taken along the Z-Z′ lines in the top views.

The optical element according to the first example is a prism lens 9A, as illustrated in (a) and (b) in FIG. 30. The prism lens 9A has the shape of a quadratic pillar with a trapezoidal cross-sectional shape. Of the lower base and upper base of the trapezoid, the lower base side that has a relatively greater width is the light-receiving face of the prism lens 9A, and the upper base side that is narrow in width is the light-emitting face. The width of the light-emitting face of the prism lens 9A is narrower than the width of the solar cell 10 by an amount equivalent to the regions with lower properties. The width of the light-receiving face of the prism lens 9A is wider than the width of the solar cell 10. Accordingly, the prism lens 9A has a light-receiving face with an area broader than the light-receiving face area of the solar cell 10, so the prism lens 9A can guide more light to the light-receiving face of the solar cell 10.

The optical element according to the second example is a CPC (Compound Parabolic Concentrator) lens 9B, as illustrated in (c) and (d) in FIG. 30. The CPC lens 9B has the shape where the side faces of the prism lens 9A have been replaced by a paraboloid face. The width of the light-receiving face of the CPC lens 9B is β/sin θ (>β), where the width of the light-emitting face of the CPC lens 9B is β and the maximum allowable incident angle at which incident light to the light-receiving face pf the CPC lens 9B can be guided to the light-emitting face is θ. The area of the light-receiving face of the CPC lens 9B is also wider than the light-receiving area of the solar cell 10, and thus can guide more light to the light-receiving face of the solar cell 10.

The optical element according to the third example is a convex lens 9C where the light-receiving face is a convex face, as illustrated in (e) and (f) in FIG. 30, and the optical element according to the fourth example is a Fresnel lens 9D where multiple diffraction gratings extending in the longitudinal direction of the solar cell 10 have been arrayed in the width direction, as illustrated in (g) and (h) in FIG. 30. The convex lens 9C and the Fresnel lens 9D both have a light-receiving face that is wider than the light-receiving area of the solar cell 10, and thus can guide more light to the light-receiving face of the solar cell 10.

### IN CONCLUSION

The solar cells 10A, 10C, 10C′, 10D, 10F, and 10G according to a first aspect of the present invention are solar cells of a rear-contact type, and include a first-conductivity type substrate (silicon substrate 1), a first region 3 made up of a first diffusion layer formed on the substrate (silicon substrate 1) and extending in a first direction (longitudinal direction) as a predetermined direction, where a first carrier of a first conductivity type is generated, a second region 4 made up of a second diffusion layer formed on the substrate (silicon substrate 1) and extending in the first direction (x direction, longitudinal direction), where a second carrier of a second conductivity type that differs from the first conductivity type is generated, a first electrode 5 disposed in the first region 3, and a second electrode 6 disposed in the second region 4. On a rear face side of the substrate (silicon substrate 1) of a quadrangular shape that has at least two sides parallel with the first direction (longitudinal direction), a plurality of the first region 3 and the second region 4 are formed alternating along a second direction (y direction, width direction) that intersects the first direction (longitudinal direction). The second region 4 is exposed at cut faces of the solar cell 10 that include the two sides and that follow a thickness direction (z direction) of the substrate (silicon substrate 1).

According to the above-describe configuration, the first carrier of the conductivity type that is the same as the conductivity type of the substrate is the majority carrier, and the second carrier of a conductivity type different from the conductivity type of the substrate is the minority carrier. The fact that the second region where the second carrier that is the minority carrier is exposed at cut faces means that the solar cell has been cut at the second region having a greater width following the second direction intersecting the first direction than the first region, at the rear face side of the quadrangular substrate having at least two sides parallel to the first direction. Accordingly, dicing can be easily performed in a region where no electrodes exist, and occurrence of chipping defects can be suppressed.

In the above-described first aspect, an arrangement may be made regarding the solar cells 10C and 10C′ according to a second aspect of the present invention, where, of the first electrodes 5 and the second electrodes 6 arrayed alternately following the second direction (width direction), one of the second electrodes 6 is situated at one end side in the second direction (width direction), and one of the first electrodes 5 is situated at another end side in the second direction (width direction), and a total number of the first electrodes 5 and the second electrodes 6 is an even number.

According to the above configuration, a case is considered where, in a large-substrate solar cell from which strip-shaped solar cells are to be cut out, a great number of first electrodes and second electrodes are arrayed alternately, and strip-shaped solar cells where an odd number of first electrodes and an odd number of second electrodes are alternately arrayed are to be cut out from this large-substrate solar cell. In this case, solar cells having the configuration according to the second aspect can be successively cut out. That is to say, according to the above configuration, in a case of dividing a large-substrate solar cell and manufacturing strip-shaped solar cells, a great number of strip-shaped solar cells, in which the way that the first electrodes and second electrodes are arrayed is the same, can be obtained.

In the above-described first aspect, an arrangement may be made regarding the solar cells 10D, 10F, and 10G according to a third aspect of the present invention, where, of the first electrodes 5 and the second electrodes 6 arrayed alternately following the second direction (width direction), one each of the second electrodes 6 is situated at both of one end side and another end side in the second direction (width direction), and a total number of the first electrodes 5 and the second electrodes 6 is an odd number.

According to the above-described configuration, second electrodes are disposed on both ends in the second direction, i.e., at both ends of the substrate in the width. The second electrodes are disposed in the second region, and the second region is wider following the second direction than the first region. Accordingly, it is easier to secure a dicing margin at both ends of the substrate.

In the above-described first aspect, regarding the solar cells 10A, 10C, 10C′, 10D, 10F, and 10G according to a fourth aspect of the present invention, preferably, the plurality of first electrodes 5 and the plurality of second electrodes 6 have side faces that extend in the first direction (longitudinal direction) and following thickness direction, and, of the side faces of the plurality of first electrodes 5 and the plurality of second electrodes 6, the side faces facing imaginary planes extending from the cut faces have a margin as to the imaginary planes.

According to the above-described configuration, the cut faces of the solar cell following the thickness direction of the substrate correspond to two parallel sides of the quadrangular substrate, and in other words, include one of each of the two sides, and are situated at both ends of the width of the substrate. Accordingly, the imaginary plane extended from the cut faces are also set at both ends in the width of the substrate. Note that the width of the substrate follows the second direction that is the direction in which the first region and the second region are arrayed alternately.

The plurality of first electrodes 5 and the plurality of second electrodes 6 extend in the first direction, and have side faces following the thickness direction, of the multiple side faces, there are side faces facing the imaginary planes. The side faces facing the imaginary planes may be either or side faces of the first electrodes and side faces of the second electrodes.

According to the above configuration, margins are provided between imaginary planes extending from cut faces, and side faces of the first electrodes or side faces of the second electrodes, and in a case of cutting out strip-shaped solar cells from large-substrate solar cell where a great number of first electrodes and second electrodes are arrayed, the concern that dicing line will cross into either of the first electrodes and second electrodes is small, and occurrence of defects can be suppressed.

In any one of the above-described first through fourth aspects, regarding the solar cells 10A, 10C, 10C′, 10D, 10F, and 10G according to fifth through seventh aspects of the present invention, the electrode patterns of the first electrodes 5 and the second electrodes 6 may be line-shaped, dot-shaped, or comb-shaped electrode patterns.

In any one of the above-described first through seventh aspects, regarding the solar cells 10A, 10C, 10C′, 10D, 10F, and 10G according to an eighth aspect of the present invention, the solar cell generates a majority carrier and a minority carrier of which conductivity types differ by receiving light, where the first carrier is the majority carrier, and the second carrier is the minority carrier. That is to say, the first carrier that is of the same conductivity type as the conductivity type of the substrate is the majority carrier, and the second carrier that is of a conductivity type different from the conductivity type of the substrate is the minority carrier, as already described.

Solar cell devices 20, 30, 40, 50, and 60 according to a ninth aspect of the present invention are solar cell devices including solar cells 10A, 10C, 10C′, 10D, 10F, and 10G, and a light collector (fluorescent light collector 8) that has a light-emitting face facing a light-receiving face of the solar cells 10A, 10C, 10C′, 10D, 10F, and 10G. The solar cells 10A, 10C, 10C′, 10D, 10F, and 10G are solar cells of a rear-contact type, and include a first-conductivity type substrate (silicon substrate 1), a first region 3 made up of a first diffusion layer formed on the substrate (silicon substrate 1) and extending in a first direction (longitudinal direction) as a predetermined direction, where a first carrier of a first conductivity type is generated, a second region 4 made up of a second diffusion layer formed on the substrate (silicon substrate 1) and extending in the first direction (longitudinal direction), where a second carrier of a second conductivity type that differs from the first conductivity type is generated, a first electrode 5 disposed in the first region 3, and a second electrode 6 disposed in the second region 4. On a rear face side of the substrate (silicon substrate 1) of a quadrangular shape that has at least two sides parallel with the first direction (longitudinal direction), a plurality of the first region 3 and the second region 4 are formed alternating along a second direction (width direction) that intersects the first direction (longitudinal direction). The second region 4 is exposed at cut faces of the solar cells 10A, 10C, 10C′, 10D, 10F, and 10G that include the two sides and that follow a thickness direction of the substrate (silicon substrate 1).

According to the above-described configuration, advantages the same as the advantages described regarding the solar cell according to the first aspect can be obtained, and further, the following advantages can be obtained.

When cutting the solar cell in the second region, the second carrier that is the minority carrier disappears due to recombination, so the electricity generating efficiency per light-receiving area deteriorates, but the solar cell device according to the ninth aspect is of a configuration including a light collector having a light-emitting face facing the light-receiving face of the solar cell, so electricity generating efficiency can be improved. That is to say, a solar cell device that has good electricity generating efficiency, and where manufacturing yield of solar cells including a cutting processing in the manufacturing processing can be improved, can be provided.

In the solar cell devices 20, 30, 40, 50, and 60 according to a tenth aspect of the present invention, the light collector in the solar cell device 20 according to the ninth aspect may be replaced with a light collecting member (fluorescent light collector 8, prism lens 9A, CPC lens 9B, convex lens 9C, Fresnel lens 9D). This tenth aspect yields advantages the same as the ninth aspect as well.

In the above-described ninth or tenth aspects, regarding the solar cell devices 20, 30, 40, 50, and 60 according to an eleventh aspect of the present invention, an arrangement may be made where a relation of d<w is satisfied, where a width of the solar cells 10A, 10C, 10C′, 10D, 10F, and 10G along the second direction (width direction) is w, and a width along the second direction (width direction) at the light-emitting face of the light collector (fluorescent light collector 8) according to the ninth aspect or the light collecting member (fluorescent light collector 8) according to the tenth aspect is d, and the light-receiving face and the light-emitting face face each other such that margins (regions Y) are formed situated at both ends in the width of the solar cells 10A, 10C, 10C′, 10D, 10F, and 10G, the margins being band-shaped and following the first direction (longitudinal direction).

According to the above-described configuration, in the margin region, the second carrier that is the minority carrier readily disappears by recombination, and the properties of the solar cell decrease, but a light collector or light collecting member is provided such that the light-emitting face faces the light-receiving face of the solar cell while avoiding this margin region. That is to say, the light collector or light collecting member is provided in a region where the effects of lower properties is small, and external light is collected, so electricity generating efficiency per light-receiving area can be improved.

In the above-described ninth or tenth aspects, regarding the solar cell devices 20, 30, 40, 50, and 60 according to a twelfth aspect of the present invention, an arrangement may be made where, with a width of the solar cells 10A, 10C, 10C′, 10D, 10F, and 10G along the second direction (width direction) being w, and a width along the second direction (width direction) at the light-emitting face of the light collector (fluorescent light collector 8) according to the ninth aspect or the light collecting member (fluorescent light collector 8) according to the tenth aspect being d, a relation of d<w is satisfied, and the width d may be d≤w−A with regard to a spacing A between the first electrode 5 and the second electrode 6.

According to the above configuration, a margin between the cut face and the first electrode or second electrode closest to the cut face exists at both ends of the solar cell in the width w. The total of the margins at both ends of the width w of the solar cell preferably does not exceed the spacing A between the first electrode and the second electrode. Dicing is performed as to the region between the first electrode and the second electrode, so in a case where the dicing position matches the middle position between the first electrode and second electrode, the total of the margins is approximately equal to the spacing A. However, if the total of the above margins exceeds the spacing A, the position of dicing is away from the middle position between the first electrode and second electrode, and electrodes will be created with a small margin at the time of dicing.

Accordingly, setting the total of margins present at both ends of the solar cell in the width w to be the spacing A, and providing the light collector or light collecting member with a width d that does not overlap the margins, i.e., d≤w−A, is preferable. Accordingly, the light-emitting face of the light collector or light collecting member can be kept from having wasteful width that would overlap the above margins (i.e., regions where photoelectric conversion properties at the light-receiving face of the solar cell has deteriorated).

In the above-described ninth or tenth aspects, regarding the solar cell devices 30 and 40 according to a thirteenth aspect of the present invention, an arrangement may be made where, of the first electrodes 5 and the second electrodes 6 arrayed alternately following the second direction (width direction), one of the second electrodes 6 is situated at one end side in the second direction (width direction), and one of the first electrodes 5 is situated at another end side in the second direction (width direction), the number of the first electrodes 5 and the second electrodes 6 is each an even number, and with a width of the solar cell along the second direction being w, and a width along the second direction at the light-emitting face of the light collector according to the ninth aspect or the light collecting member according to the tenth aspect being d, and a spacing between the first electrode and the second electrode being spacing A, and width of the first electrodes 5 and the second electrodes 6 following the second direction (width direction) being width B and width C respectively, the width d is d≤w−A−B−C.

According to the above-described configuration, in a solar cell where the number of first electrodes and second electrodes is each an even number, the width B of the first electrode at one end side of the solar cell in the width w and the width C of the second electrode at another end side of the solar cell in the width w are further subtracted from the width w of the solar cell. Accordingly, the effects of positional deviation that can occur when placing the light-emitting face of the light collector or light collecting member on the light-receiving face of the solar cell can be reduced. That is to say, trouble where the light-emitting face of the light collector or light collecting member overlaps the above-described margins due to the above positional deviation can be avoided more readily.

In the above-described ninth or tenth aspects, regarding the solar cell devices 20, 50, and 60 according to a fourteenth aspect of the present invention, an arrangement may be made where, of the first electrodes 5 and the second electrodes 6 arrayed alternately following the second direction (width direction), one of the second electrodes 6 is situated at each of one end side and another end side in the second direction (width direction), and a total number of the first electrodes 5 and the second electrodes 6 is an odd number, and with a width of the solar cell along the second direction being w, and a width along the second direction at the light-emitting face of the light collector according to the ninth aspect or the light collecting member according to the tenth aspect being d, and a spacing between the first electrode and the second electrode being spacing A, and width of the second electrodes following the second direction (width direction) being width C, the width d is d≤w−A−2C.

According to the above-described configuration, in a solar cell where the number of first electrodes and second electrodes is an odd number, the widths C of the second electrodes at one end side and another end side of the solar cell in the width w are further subtracted from the width w of the solar cell. Accordingly, the effects of positional deviation that can occur when placing the light-emitting face of the light collector or light collecting member on the light-receiving face of the solar cell can be reduced. That is to say, trouble where the light-emitting face of the light collector or light collecting member overlaps the above-described margins due to the above positional deviation can be avoided more readily.

In the above-described ninth or tenth aspects, regarding the solar cell devices 20, 30, 40, 50, and 60 according to a fifteenth aspect of the present invention, an arrangement may be made where, with a width of the solar cell along the second direction being w, and a width along the second direction at the light-emitting face of the light collector according to the ninth aspect or the light collecting member according to the tenth aspect being d, and a spacing between the first electrode and the second electrode being spacing A, and width of the first electrodes 5 and the second electrodes 6 following the second direction (width direction) being width B and width C respectively, the width d is d≤w−3A−2B−2C.

According to the above-described configuration, the width B of the first electrode and the width C of the second electrode at one end side and another end side of the solar cell in the width w, and the spacing A between the first electrode and second electrode, are further subtracted from the width w of the solar cell, regardless of whether the number of first electrodes and second electrodes is each an even number or odd number. Accordingly, the effects of positional deviation that can occur when placing the light-emitting face of the light collector or light collecting member on the light-receiving face of the solar cell can be further reduced. That is to say, trouble where the light-emitting face of the light collector or light collecting member overlaps the above-described margins due to the above positional deviation can be avoided even more readily.

In the solar cell devices 20, 30, 40, 50, and 60 according to a sixteenth aspect of the present invention, the light collecting member according to any one of the tenth through fifteenth aspects may be the fluorescent light collector 8 or an optical element having functions of a condenser lens (prism lens 9A, CPC lens 9B, convex lens 9C, or Fresnel lens 9D).

According to the above-described configuration, a fluorescent light collector where a fluorescent substance is dispersed within the light collector can improve electricity generating efficiency of the solar cell. This is because the fluorescent substance absorbs light of a particular wavelength band and emits light of a different wavelength band, so the quantity of light of that other wavelength band can be increased.

The optical element having the function of a condenser lens collects external light that has been taken in onto the light-receiving face of the solar cell, and thus can improve electricity generating efficiency of the solar cell. Further, the optical element has a light-receiving face for taking in external light, and the light-receiving face of the optical element can be set to be larger than the light-receiving face of the solar cell, and thus has an advantage that the electricity generating efficiency of the solar cell can be readily improved even further.

In any one of the above-described ninth through sixteenth aspects, regarding the solar cell devices 20, 30, 40, 50, and 60 according to seventeenth through nineteenth aspects of the present invention, the electrode patterns of the first electrodes 5 and the second electrodes 6 may be line-shaped, dot-shaped, or comb-shaped electrode patterns.

A manufacturing method of solar cells 10A, 10C, 10C′, 10D, 10F, and 10G, according to a twentieth aspect of the present invention includes forming, on a first-conductivity type substrate (silicon substrate 1), a first region 3 made up of a first diffusion layer where a first carrier of a first conductivity type is generated, and a second region 4 made up of a second diffusion layer where a second carrier of a second conductivity type that differs from the first conductivity type is generated, each extending in a first direction (longitudinal direction) as a predetermined direction, the first region 3 and the second region 4 being formed alternating along a second direction (width direction) that intersects the first direction (longitudinal direction), forming a first electrode 5 in the first region 3, and a second electrode 6 in the second region 4, and cutting the second region 4 between the first electrode 5 and the second electrode 6 following the first direction (longitudinal direction), thereby fabricating quadrangle-shaped solar cells 10A, 10C, 10C′, 10D, 10F, and 10G having two sides parallel with the first direction (longitudinal direction).

According to the above-described method, the second region having a width in the second direction that is greater than the first region is cut following the first direction, so a wide dicing margin can be secured for example. Also, cutting is performed in a region where no electrodes exist, so occurrence of chipping defects can be suppressed. Accordingly, good-quality strip-shaped solar cells can be easily fabricated.

A manufacturing method of a solar cell device according to a twenty-first aspect of the present invention is a manufacturing method of solar cell devices 20, 30, 40, 50, and 60 including solar cells 10A, 10C, 10C′, 10D, 10F, and 10G and a light collector (fluorescent light collector 8), including forming, on a first-conductivity type substrate (silicon substrate 1), a first region 3 made up of a first diffusion layer where a first carrier of a first conductivity type is generated, and a second region 4 made up of a second diffusion layer where a second carrier of a second conductivity type that differs from the first conductivity type is generated, each extending in a first direction as a predetermined direction, the first region 3 and the second region 4 being formed alternating along a second direction that intersects the first direction, forming a first electrode 5 in the first region 3, and a second electrode 6 in the second region 4, and cutting the second region 4 between the first electrode 5 and the second electrode 6 following the first direction, thereby fabricating quadrangle-shaped solar cells 10A, 10C, 10C′, 10D, 10F, and 10G having two sides parallel with the first direction, and assembling the light collector (fluorescent light collector 8) with the light-emitting face of the light collector (fluorescent light collector 8) facing the light-receiving face of the fabricated solar cells 10A, 10C, 10C′, 10D, 10F, and 10G.

According to the above-described method, the second region having a width in the particular direction that is greater than the first region is cut following the extending direction, so a wide dicing margin can be secured for example. Also, cutting is performed in a region where no electrodes exist, so occurrence of chipping defects can be suppressed. Accordingly, good-quality strip-shaped solar cells can be easily fabricated.

Further, cutting the solar cell at the second region results in the electricity generating efficiency per light-receiving are decreasing due to the second carrier that is the minority carrier disappearing by recombination, but a light collector is assembled such that the light-emitting face faces the light-receiving face of the solar cell in the manufacturing method according to the twenty-first aspect, so electricity generating efficiency can be improved. That is to say, a solar cell device that has good electricity generating efficiency, and where manufacturing yield of solar cells including a cutting processing in the manufacturing processing can be improved, can be provided.

In the manufacturing method of the solar cell devices 20, 30, 40, 50, and 60 according to a twenty-second aspect of the present invention, the light collector in the manufacturing method of the solar cell devices 20, 30, 40, 50, and 60 according to the twenty-first aspect may be replaced with a light collecting member (fluorescent light collector 8, prism lens 9A, CPC lens 9B, convex lens 9C, or Fresnel lens 9D), and thereby obtain advantages the same as the twenty-first aspect.

The present invention is not restricted to the above-described embodiments, rather, various modifications can be made without departing from the scope of the Claims, and embodiments obtained by appropriately combining technical means disclosed in different embodiments are also included in the technical scope of the present invention. Further, new technical features can be formed by combining technical means disclosed in the embodiments.

### CROSS-REFERENCE TO RELATED APPLICATIONS

the present application claims the benefit of Japanese Patent Application No. 2016-081435 filed Apr. 14, 2016, which is hereby incorporated by reference herein in its entirety.

### INDUSTRIAL APPLICABILITY

The present invention can be used in a fluorescent light collecting solar cell having a fluorescent light collector.

### REFERENCE SIGNS LIST

1 silicon substrate (first-conductivity type substrate)
3 first region
4 second region
5, 5a, 5b first electrode
6, 6a, 6b second electrode
8 fluorescent light collector (light collector)
9A prism lens (light collecting member)
9B CPC lens (light collecting member)
9C convex lens (light collecting member)
9D Fresnel lens (light collecting member)
10, 10a, 10b, 10c, 10f solar cell
10A, 10C, 10C′, 10F, 10F1 through 10F4, 10G strip-shaped solar cell
20, 30, 40, 50, 60 solar cell device
X dicing lines
Y, Y1, Y2 regions
A spacing
B width of first electrode
C width of second electrode
d width
p repeating pitch
w, w′, w″ width

1.-22. (canceled)

23. A solar cell device, comprising: a solar cell; and a light collector that has a light-emitting face facing a light-receiving face of the solar cell,
wherein the solar cell is a rear-contact type solar cell, including
a first-conductivity type substrate,
a first region made up of a first diffusion layer formed on the substrate and extending in a first direction as a predetermined direction, where a first carrier of a first conductivity type is generated,
a second region made up of a second diffusion layer formed on the substrate and extending in the first direction, where a second carrier of a second conductivity type that differs from the first conductivity type is generated,
a first electrode disposed in the first region, and
a second electrode disposed in the second region,
wherein, on a rear face side of the substrate of a quadrangular shape that has at least two sides parallel with the first direction, a plurality of the first region and the second region are formed alternating along a second direction that intersects the first direction,
and wherein the second region is exposed at cut faces of the solar cell that include the two sides and that follow a thickness direction of the substrate.

24. The solar cell device according to claim 23,
wherein a relation of d<w is satisfied, where a width of the solar cell along the second direction is w, and wherein a width along the second direction at the light-emitting face of the light collector is d,
and wherein the light-receiving face and the light-emitting face face each other such that margins are formed situated at both ends in the width of the solar cell, the margins being band-shaped and following the first direction.

25. The solar cell device according to claim 23,
wherein with a width of the solar cell along the second direction being w, and a width along the second direction at the light-emitting face of the light collector being d,
and a spacing between the first electrode and the second electrode being spacing A,
the width d is d≤w−A.

26. The solar cell device according to claim 23,
wherein, of the first electrodes and the second electrodes arrayed alternately following the second direction, one of the second electrodes is situated at one end side in the second direction, and one of the first electrodes is situated at another end side in the second direction,
wherein the number of the first electrodes and the second electrodes is each an even number,
wherein with a width of the solar cell along the second direction being w, and a width along the second direction at the light-emitting face of the light collector being d,
and a spacing between the first electrode and the second electrode being spacing A,
and width of the first electrodes and the second electrodes following the second direction being width B and width C respectively,
the width d is d≤w−A−B−C.

27. The solar cell device according to claim 23,
wherein, of the first electrodes and the second electrodes arrayed alternately following the second direction, one of the second electrodes is situated at each of one end side and another end side in the second direction,
wherein a total number of the first electrodes and the second electrodes is an odd number,
wherein with a width of the solar cell along the second direction being w, and a width along the second direction at the light-emitting face of the light collector being d,
and a spacing between the first electrode and the second electrode being spacing A,
and width of the second electrodes following the second direction being width C,
the width d is d≤w−A−2C.

28. The solar cell device according to claim 23,
wherein, with a width of the solar cell along the second direction being w, and a width along the second direction at the light-emitting face of the light collector being d,
and a spacing between the first electrode and the second electrode being spacing A,
and width of the first electrodes and the second electrodes following the second direction being width B and width C respectively,
the width d is d≤w−3A−2B−2C.

29. The solar cell device according to claim 23,
wherein the first electrodes and second electrodes are line-shaped electrode patterns.

30. The solar cell device according to claim 23,
wherein the first electrodes and second electrodes are dot-shaped electrode patterns.

31. The solar cell device according to claim 23,
wherein the first electrodes and second electrodes are comb-shaped electrode patterns.

32. A solar cell device, comprising: a solar cell; and a light collecting member that has a light-emitting face facing a light-receiving face of the solar cell,
wherein the solar cell is a rear-contact type solar cell, including
a first-conductivity type substrate,
a first region made up of a first diffusion layer formed on the substrate and extending in a first direction as a predetermined direction, where a first carrier of a first conductivity type is generated,
a second region made up of a second diffusion layer formed on the substrate and extending in the first direction, where a second carrier of a second conductivity type that differs from the first conductivity type is generated,
a first electrode disposed in the first region, and
a second electrode disposed in the second region,
wherein, on a rear face side of the substrate of a quadrangular shape that has at least two sides parallel with the first direction, a plurality of the first region and the second region are formed alternating along a second direction that intersects the first direction,
and wherein the second region is exposed at cut faces of the solar cell that include the two sides and that follow a thickness direction of the substrate.

33. The solar cell device according to claim 32,
wherein a relation of d<w is satisfied, where a width of the solar cell along the second direction is w, and wherein a width along the second direction at the light-emitting face of the light collecting member is d,
and wherein the light-receiving face and the light-emitting face face each other such that margins are formed situated at both ends in the width of the solar cell, the margins being band-shaped and following the first direction.

34. The solar cell device according to claim 32,
wherein with a width of the solar cell along the second direction being w, and a width along the second direction at the light-emitting face of the light collecting member being d,
and a spacing between the first electrode and the second electrode being spacing A,
the width d is d≤w−A.

35. The solar cell device according to claim 32,
wherein, of the first electrodes and the second electrodes arrayed alternately following the second direction, one of the second electrodes is situated at one end side in the second direction, and one of the first electrodes is situated at another end side in the second direction,
wherein the number of the first electrodes and the second electrodes is each an even number,
wherein with a width of the solar cell along the second direction being w, and a width along the second direction at the light-emitting face of the light collecting member being d,
and a spacing between the first electrode and the second electrode being spacing A,
and width of the first electrodes and the second electrodes following the second direction being width B and width C respectively,
the width d is d≤w−A−B−C.

36. The solar cell device according to claim 32,
wherein, of the first electrodes and the second electrodes arrayed alternately following the second direction, one of the second electrodes is situated at each of one end side and another end side in the second direction,
wherein a total number of the first electrodes and the second electrodes is an odd number,
wherein with a width of the solar cell along the second direction being w, and a width along the second direction at the light-emitting face of the light collecting member being d,
and a spacing between the first electrode and the second electrode being spacing A,
and width of the second electrodes following the second direction being width C,
the width d is d≤w−A−2C.

37. The solar cell device according to claim 32,
wherein, with a width of the solar cell along the second direction being w, and a width along the second direction at the light-emitting face of the light collecting member being d,
and a spacing between the first electrode and the second electrode being spacing A,
and width of the first electrodes and the second electrodes following the second direction being width B and width C respectively,
the width d is d≤w−3A−2B−2C.

38. The solar cell device according to claim 32,
wherein the light collecting member is fluorescent light collector or an optical element having functions of a condenser lens.

39. The solar cell device according to claim 32,
wherein the first electrodes and second electrodes are line-shaped electrode patterns.

40. The solar cell device according to claim 32,
wherein the first electrodes and second electrodes are dot-shaped electrode patterns.

41. The solar cell device according to claim 32,
wherein the first electrodes and second electrodes are comb-shaped electrode patterns.
